(19) United States
(12) Patent Application Publication
(10) Pub. No.: US 2006/0289203 A1
(43) Pub. Date: Dec. 28, 2006

(54) Double-sided wiring board, double sided wiring board manufacturing method, and multilayer wiring board

(75) Inventor: Kazunori Oda, Tokyo-to (JP)

Correspondence Address: OLIFF & BERRIDGE, PLC, P.O. BOX 19928, ALEXANDRIA, VA, 22320, US

(73) Assignee: DAI NIPPON PRINTING CO., LTD., Tokyo-to (JP)

(21) Appl. No.: 10/557,788

(22) PCT Filed: May 18, 2004
(86) PCT No.: PCT/JP04/06649

§ 371 Date: Nov. 18, 2005

(30) Foreign Application Priority Data
May 19, 2003 (JP) 2003140293
May 30, 2003 (JP) 2003153645
Dec. 22, 2003 (JP) 2003424663

(51) Int. Cl. H05K 1/11; H05K 1/09; H05K 3/42

(52) U.S. Cl. 174/264; 174/265; 174/257; 29/852

(57) ABSTRACT

A single wiring layer is formed on each of both the roughened surfaces of a core substrate by a semiadditive method. The wiring layers formed on the surfaces of the core substrate are electrically connected through a through hole formed in the core substrate. The through hole is formed in the core substrate by laser machining. The through hole is filled up with conductive a plug. Both the surfaces of the core substrate are coated with solder resist layers, respectively, with predetermined terminal parts of the wiring layers exposed through openings formed in the solder resist layers. End surfaces of the conductive plug filling up the through holes, and the surfaces of the wiring layers are planarized by mechanical or chemical-mechanical polishing.

### TECHNICAL FIELD

The present invention relates to a double-sided wiring board including a core substrate, wiring layers formed on both surfaces of the core substrate and electrically connected by a through hole formed in the core substrate, exposed terminals, and solder resist layers covering both surfaces of the core substrate, and a method of fabricating the double-sided wiring board.

### BACKGROUND ART

Various buildup multilayer wiring boards capable of containing fine wiring patterns in a high pattern density, as compared with conventional laminated wiring boards, and methods of fabricating such buildup multilayer wiring boards have been developed to cope with the size- and weight-reduction of electronic devices. The buildup multilayer wiring board is formed by sequentially building up insulating layers and wiring layers on each of the surfaces of a core substrate provided with wiring layers on its surfaces.

Semiconductor parts for electronic devices are required to be packaged in a high packaging density to cope with the size-reduction of electronic devices. A flip-chip technique that bonds a semiconductor IC chip face-down to a wiring board, such as a mother board, has gained wide attention in recent years.

Recently, by using a buildup multilayer wiring board as an interposer, a semiconductor IC chip has been bonded to the double-sided wiring board by the flip-chip technique or wire bonding technique.

For example, as shown in FIG. 9, a semiconductor IC chip 20 is bonded face-down on a solder resist layer 12 formed on a multilayer wiring board 10 with solder bumps 21 by the flip-chip technique, a gap between the semiconductor IC chip 20 and the solder resist layer 12 formed on the multilayer wiring board 10 is filled up with an underfill 30, and then the semiconductor IC chip 20, the solder bumps 21 and wiring lines 11 are sealed in a sealing resin 40.

Flip chips are bare chips provided with Au or solder bumps, i.e., connecting protrusions, having terminals arranged in an area array to meet requirements for increasing pins, satisfactory high-frequency characteristics and miniaturization, and packaged at small pitches.

The flip-chip technique was put to practical use in 1963 by IBM. The flip-chip technique connects the bumps of a flip chip to the electrodes of a wiring board. The flip-chip technique achieves simultaneously work for mounting a flip chip on a wiring board and work for connecting the flip chip electrically to the circuits formed on the wiring board, and hence time necessary for assembling the flip-chip and the wiring board does not increase even if the number of pins increases. Thus, the flip-chip technique is an excellent chip-mounting technique to cope with increase in the number of pins per chip.

A core substrate fabricating method of fabricating a core substrate for a conventional buildup board will be briefly described with reference to FIG. 7.

First, through holes 715 are formed mechanically by a drilling machine in a Cu-clad laminated plate 710 formed by laminating Cu foils 712 to both the surfaces of a core plate 711 (FIG. 7(a)).

Subsequently, the through holes 715 are cleaned, and plated Cu films 720 of a predetermined thickness are formed over all the exposed surfaces of the Cu-clad laminated plate 710 by electroless plating such that the side surfaces of the through holes 715 (FIG. 7(a)) are metallized. Then, plated Cu films 730 of a predetermined thickness are formed over all the side surfaces of the through holes 715 by Cu-electroplating to connect the conductive side surfaces of the through holes 715 to the Cu foils 712 (FIG. 7(b)).

Then, the through holes 715 are filled up with a filler 740, i.e., conductive metallic material or a nonconductive paste, to polish the side surfaces of the through holes 715 by physical polishing (FIG. 7(c)).

Then, resist films, such as dry resist films or resist films of a liquid resist, are formed on the core plate 711, the resist films are exposed through masks of a predetermined pattern, and the exposed resist films are developed to form patterned resist films. The plated Cu films 730, the Cu films 720 formed by electroless plating, and the Cu foils 712 are etched through the patterned resist films, i.e., masks, to form plated through holes 750 and desired wiring lines, not shown, to complete a core substrate 760 (FIG. 7(d)).

Wiring lines are formed in a high density by a buildup method on both surfaces of the core substrate 760 (FIG. 7(d)) thus formed to fabricate a buildup multilayer wiring board. The buildup multilayer wiring board is used as an interposer for a semiconductor IC package as shown in FIG. 8 by way of example.

A multilayer wiring board 810 shown in FIG. 8 can be fabricated by the following method. Insulating layers 851 and 851a of a glass fabric impregnated with a resin, such as prepregs, or a resin are formed on both surfaces of the core substrate 760 (FIG. 7(d)). Small holes are formed at predetermined positions on the insulating layers 851 and 851a by laser machining using a CO₂ laser or a UV-YAG laser such that the plated through holes 750 (FIG. 7(d)) formed in the core substrate 760, and desired parts of the wiring lines are exposed.

The core substrate 760 thus processed is cleaned, and conductive layers are formed in the small holes by electroless plating. Dry resist films are laminated to the surfaces of the core substrate 760 and are patterned in predetermined patterns to form masks. Vias 871 are formed on the exposed parts including the small holes by electroplating to form first buildup layers.

Those steps are repeated to form a plurality of buildup layers on the core substrate 760 to form a multilayer wiring board 810. The multilayer wiring board 810 shown in FIG. 8 is provided with two buildup layers on each of the surfaces of the core substrate 760.

The buildup layer on which a semiconductor IC chip is to be mounted is provided with necessary wiring lines and connection pads 865 to which the semiconductor IC chip is bonded.

Solder resist layers 885 are formed on the surfaces of the multilayer wiring board 810 so that the connection pads 865 and 855 are exposed.

A semiconductor IC chip 890 is connected to the connection pads 865 of the multilayer wiring board 810 by metal bumps 891, such as solder bumps.

The multilayer wiring board 810 is mounted on a printed wiring board, such as a mother board, and terminals 880 formed on the back surface of the multilayer wiring board 810 are connected to the terminals of the printed wiring board.

FIG. 8 shows a part of the multilayer wiring board in a simple, typical view.

Naturally, a semiconductor IC chip may be connected to the circuits of the buildup multilayer wiring board shown in FIG. 8 by wire bonding and the multilayer wiring board can be used as an interposer for a semiconductor IC package.

The core substrate 760 shown in FIG. 7 formed by the conventional core substrate fabricating method is provided with the through holes formed by mechanical drilling, and the wiring lines formed by a subtractive method. It is difficult to form the through holes in a diameter below about 150 μm and to form lands in a diameter below about 350 μm. It is difficult to form the lines in a width of 50 μm or below in a spacing of 50 μm or below by the subtractive method.

Wiring lines cannot be formed in a high density in only this core substrate 760. Practically, a buildup multilayer wiring board provided with two buildup layers as shown in FIG. 8 or with one buildup layer is used as an interposer for a semiconductor IC package to achieve high-density wiring and to cope with limits to wiring. However, the fabrication of this buildup multilayer wiring board needs many processes, which directly increase the cost.

The wiring board as shown in FIG. 8 suffers from large power loss caused by the through holes and hence is unsuitable for uses that deal with high-frequency electricity.

Refer to Jpn. Pat. App. No. 2002-299665 (JP-A 2004-134679).

Problems arise in wiring density and wiring arrangement when the core substrate formed by the conventional subtractive process is applied directly to a wiring board for a semiconductor IC package. A buildup multilayer wiring board fabricated by forming buildup layers on both surfaces of a core substrate is currently used as a wiring board for an IC package. However, fabrication of such a buildup multilayer wiring board requires many complicated processes and large cost, and is unsuitable for uses that deal with high-frequency electricity because the through holes cause large power loss. There has been a demand for a wiring board that solves those problems.

### DISCLOSURE OF THE INVENTION

The present invention has been made to solve those problems and it is therefore an object of the present invention to provide a wiring board for an IC package, suitable for high-density packaging, and capable of being produced at a productivity higher than that at which the conventional buildup multilayer wiring board can be produced and of solving problems attributable to high-frequency power loss.

Another object of the present invention is to provide a wiring board for an IC package, resistant to lateral sliding during wire bonding or flip-chip solder bonding for assembling a semiconductor device, provided with filled through holes not having any dents and wiring layers of a uniform thickness.

A third object of the present invention is to provide a wiring board fabricating method of fabricating the foregoing wiring board according to the present invention.

According to the present invention, a double-sided wiring board includes a core substrate having two roughened surfaces; and wiring layers formed on both the surfaces of the core substrate, respectively; wherein the wiring layers are electrically connected through a through hole formed in the core substrate.

In the double-sided wiring board according to the present invention, a conductive plug is formed in the through hole by filling up the through hole with a conductive material.

In the double-sided wiring board according to the present invention, solder resist layers are formed on the wiring layers formed on both the surfaces of the core substrate so as to expose terminals.

In the double-sided wiring board according to the present invention, the outer surfaces of the wiring layers formed on both the surfaces of the core substrate are flush with the end surfaces of the conductive plugs.

In the double-sided wiring board according to the present invention, both the surfaces of the core substrate have a ten-point height irregularity Rz specified in JIS in the range of 2 to 10 μm.

In the double-sided wiring board according to the present invention, the double-sided wiring board is a board for a semiconductor IC package.

In the double-sided wiring board according to the present invention, the terminals formed on one of the surfaces of the core substrate are connection pads to be connected to a semiconductor chip, and the terminals formed on the other surface are those to be connected to external circuits.

In the double-sided wiring board according to the present invention, each of terminals formed on both the surfaces of the core substrate has a plated Ni layer and a plated Au layer formed in that order.

The planarization process herein is for planarizing the outer surfaces of wiring lines of the wiring layers including the end surfaces of the plugs filling up the through holes are flat and contained in planes, respectively. The planarization process is achieved by mechanical or chemical-mechanical polishing. When the core substrate is used for forming a wiring board for an IC package, deviations of the surfaces of the wiring lines of a core substrate from a reference plane is within ±5 μm.

In the specification, a ten point height irregularity Rz specified in JIS is defined and indicated in line with JIS B0601-2001.

In JIS B0601-2001, a part of a reference length is taken out from a roughness curve in a direction of an average line. An average value of absolute values of altitudes of the highest to the fifth highest peaks measured from the average line of the taken-out part in a longitudinal magnification direction is calculated. An average value of absolute values of altitudes of the lowest to the fifth lowest valleys measured from the average line of the taken-out part in a longitudinal magnification direction is calculated. A sum of the above average values indicated by using a unit μm is referred to as a ten point height irregularity Rz (JIS). The reference length herein is 0.25 mm.

The solder resist layers are formed on the surfaces of the core substrate so as to expose terminals. Thus, openings can be formed in the solder resist layers so that predetermined terminal regions are exposed. In addition, the solder resist layers can be formed on the surfaces of the core substrate so that predetermined terminal regions are exposed and semiconductor chip mounting regions on the double-sided wiring board are exposed.

In the double-sided wiring board according to the present invention, the side surface of the through hole is coated with a plated conductive layer, and the through hole is filled up with a resist.

In the double-sided wiring board according to the present invention, solder resist layers are formed on the wiring layers formed on both the surfaces of the core substrate so that terminals are exposed.

In the double-sided wiring board according to the present invention, both the surfaces of the core substrate have a ten-point height irregularity Rz specified in JIS in the range of 2 to 10 μm.

In the double-sided wiring board according to the present invention, the double-sided wiring board is a board for a semiconductor IC package.

In the double-sided wiring board according to the present invention, the terminals formed on one of the surfaces of the core substrate are connection pads to be connected to a semiconductor chip, and the terminals formed on the other surface are those to be connected to external circuits.

In the double-sided wiring board according to the present invention, each of terminals formed on both the surfaces of the core substrate has a plated Ni layer and a plated Au layer formed in that order.

In the specification, a ten point height irregularity Rz specified in JIS is defined and indicated in line with JIS B0601-2001.

In JIS B0601-2001, a part of a reference length is taken out from a roughness curve in a direction of an average line. An average value of absolute values of altitudes of the highest to the fifth highest peaks measured from the average line of the taken-out part in a longitudinal magnification direction is calculated. An average value of absolute values of altitudes of the lowest to the fifth lowest valleys measured from the average line of the taken-out part in a longitudinal magnification direction is calculated. A sum of the above average values indicated by using a unit μm is referred to as a ten point height irregularity Rz (JIS). The reference length herein is 0.25 mm.

In the double-sided wiring board according to the present invention, the through hole of the core substrate has a trapezoidal cross section.

In the double-sided wiring board according to the present invention, the through hole of the core substrate has a first trapezoidal cross section which is tapered from one end of the through hole toward inside, and a second trapezoidal cross section which is tapered from the other end of the through hole to the inside.

In the double-sided wiring board according to the present invention, the first trapezoidal cross section of the through hole is larger than the second trapezoidal cross section thereof.

According to the present invention, a double-sided wiring board fabricating method of fabricating a double-sided wiring board including a core substrate having two roughened surfaces, and wiring layers formed on both the surfaces of the core substrate and electrically connected through a through hole formed in the core substrate includes the steps of: laminating Cu foils each having a roughened surface to the surfaces of an insulating resin film for forming the core substrate with the roughened surfaces thereof in contact with the insulating resin film, respectively, by a contact-bonding process; removing the Cu foils attached to the insulating resin film by an etching process and transferring the shapes of the roughened surfaces of the Cu foils to the surfaces of the insulating resin film to form the core substrate; forming a through hole in the core substrate by a laser machining process; forming electroless-plated layers on the surfaces of the core substrate and the side surface of the through hole by an electroless plating process; forming electroplated Cu layers by a Cu-electroplating process using the electroless-plated layers as conductive layers after forming patterned resist layers on the surfaces of the core substrate; and removing exposed unnecessary parts of the electroless-plated layers by a flash etching process after removing the patterned resist layers.

In the double-sided wiring board fabricating method according to the present invention, a conductive plug is formed so as to fill up the through hole when the electroplated Cu layers are formed.

In the double-sided wiring board fabricating method according to the present invention, the side surface of the through hole is subjected to a desmearing process before forming the electroless-plated layers.

In the double-sided wiring board fabricating method according to the present invention, the electroplated Cu layers are planarized by mechanical or chemical-mechanical polishing.

The double-sided wiring board fabricating method according to the present invention further includes the steps of: after removing the electroless-plated layers by flash etching, forming solder resist layers of a photosensitive solder resist on the electroplated Cu layers formed on the surfaces of the core substrate; and exposing the solder resist layers through masks, and developing the exposed solder resist layers to expose parts of the electroplated Cu layers to form terminals.

In the double-sided wiring board fabricating method according to the present invention, the roughened surfaces of the Cu foils to be attached by the contact-bonding process to the insulating resin film have a ten-point height irregularity Rz specified in JIS in the range of 2 to 10 μm.

In the double-sided wiring board fabricating method according to the present invention, the through hole is formed in the core substrate by placing a plate that does not excessively reflect a laser beam on one of the surfaces of the core substrate, and irradiating the core substrate from the side of the other surface of the core substrate with a laser beam.

In the double-sided wiring board fabricating method according to the present invention, a plated Ni layer and a plated Au layer are formed in that order on the surface of each of the terminals.

In the double-sided wiring board fabricating method according to the present invention, dry resist films are applied to the surfaces of the core substrate, the dry resist films are exposed through masks, and the exposed dry resist films are exposed to form the patterned resist films when the electroplated Cu layers are formed.

The double-sided wiring board fabricating method according to the present invention further includes the steps of: after removing the electroless-plated layers by a flash etching process, forming solder resist layers on the surfaces of the electroplated Cu layers formed on the core substrate by applying a photosensitive solder resist to the electroplated Cu layers and filling up the through hole with the solder resist; and exposing parts of the electroplated Cu layers to form terminals by exposing the solder resist layers through masks, and developing the exposed solder resist layers.

In the double-sided wiring board fabricating method according to the present invention, the roughened surfaces of the Cu foils to be attached by the contact-bonding process to the insulating resin film have a ten-point height irregularity Rz specified in JIS in the range of 2 to 10 μm.

In the double-sided wiring board fabricating method according to the present invention, the through hole is formed in the core substrate by placing a plate that does not excessively reflect a laser beam on one of the surfaces of the core substrate, and irradiating the core substrate from the side of the other surface of the core substrate with a laser beam.

In the double-sided wiring board fabricating method according to the present invention, a plated Ni layer and a plated Au layer are formed in that order on the surface of each of the terminals.

In the double-sided wiring board fabricating method according to the present invention, the electroplated Cu layers are formed by applying dry resist films to the surfaces of the core substrate, exposing the dry resist films through masks, and developing the exposed dry resist films to form the patterned resist films.

In this specification, terminal, lands and connecting lines will be referred to inclusively as wiring parts. The term “wiring lines” sometimes signifies terminals and lands in addition to connecting lines.

The electroplated Cu layers are planarized by a planarization process so that the surfaces of the electroplated Cu layers are flat and contained in planes, respectively. The planarization process is achieved by mechanical or chemical-mechanical polishing. When the core substrate is used for forming a wiring board for an IC package, deviations of the surfaces of the wiring lines of a core substrate from a reference plane is within ±5 μm.

The double-sided wiring board of the present invention thus fabricated is suitable for high-density packaging and is excellent, as compared with the conventional buildup multilayer wiring board, in respect of productivity and high-frequency power loss.

More specifically, the through hole is formed in a diameter of 150 μm or below in the core substrate by laser machining.

Naturally, the through hole can be formed in diameters greater than 150 μm.

The through hole formed in the core substrate by laser machining may be a taper through hole having a trapezoidal cross section and tapered from one side of the core substrate from which a laser beam falls on the core substrate toward the other side of the core substrate. Such a taper through hole facilitates filling up the through hole with a plug by plating. The through hole is filled up with the plugs each having opposite flat ends and the solder resist layers can be formed on the opposite ends of the plugs. Laser machining forms the through hole efficiently in the core substrate and the core substrate has excellent quality.

Since the through hole is filled up with the conductive plug by plating and a region provided with the through hole is flat, terminals (pads) can be formed in regions provided with the through hole.

Thus, a pad-on-through hole design is possible, the degree of freedom of design is large, and wiring lines can be arranged in a high density.

The through hole of the conventional core substrate is formed by mechanical drilling and hence the through hole cannot be formed in diameters not greater than 150 μm.

Both the surfaces of the core substrate are roughened to enable forming wiring lines by a semiadditive method, and fine wiring lines can be formed in a high density by the semiadditive method.

Moreover, the region provided with the through hole is flat, and via holes can be surely formed on the flat region provided with the through hole by a buildup method for forming multiple wiring layers without using the solder resist. A method of forming a multilayer wiring board can be surely achieved by laminating Cu foils to insulating layers formed on the surfaces of the core substrate on which wiring layers are to be formed, forming wiring layers by etching the Cu foils by a photolithographic etching process, and connecting the wiring layers with bumps.

Thus, when the double-sided wiring board is used for forming a semiconductor IC package, wiring lines can be arranged in an arrangement in which wiring lines cannot be arranged when a core substrate as shown in FIG. 7(d) is used as an interposer for a semiconductor IC package. The double-sided wiring board of the present invention can be used instead of a buildup multilayer wiring board provided with at least one buildup layer.

The outer surfaces of wiring lines of the wiring layers including the end surfaces of the plugs filling up the through hole are planarized by mechanical or chemical-mechanical polishing. Therefore, semiconductor chips rarely slide when the semiconductor chips are mounted on the wiring board by wire bonding or flip-chip solder bonding, a conductive plug filling up the through hole does not have any dents, and the wiring lines have a uniform thickness.

Practically, it is preferable that both the roughened surfaces of the core substrate have a ten-point height irregularity Rz (JIS) in the range of 2 to 10 μm.

The adhesion of the wiring lines to the surfaces of the core substrate is not sufficient when the surface roughness Rz (JIS) is smaller than 2 μm, and irregularities in the surfaces of the core substrate affect adversely to the shape of wiring lines, hinder the miniaturization of wiring lines and increases load on the manufacture of the electrolytic Cu foils when the surface roughness Rz (JIS) is greater than 10 μm.

The double-sided wiring board of the present invention, as compared with the buildup multilayer wiring board, is excellent in productivity.

A double-sided wiring board according to the present invention has one surface provided with connection pads to mount a semiconductor chip on the same surface by flip-chip solder bonding or wire bonding, and the other surface provided with terminals to which external circuits are to be connected.

In this case, openings are formed in a solder resist layer so that predetermined terminal regions are exposed or so that predetermined terminal regions are exposed and semiconductor chip mounting regions on the double-sided wiring board are exposed.

Particularly, the through hole region is flat and a semiconductor chip can be directly mounted on the double-sided wiring board without forming a solder resist layer.

When a semiconductor chip is directly mounted on the double-sided wiring board, the bumps of the semiconductor chip are free from restrictions, which is advantageous to flip-chip solder bonding. Any bubbles are not included in the through hole when a semiconductor chip is mounted on the double-sided wiring board.

Generally, the terminals are coated with a plated Ni layer and a plated Au layer.

Buildup layers can be formed on both the surfaces of the double-sided wiring board of the present invention not provided with any solder resist layers on its both surfaces. Thus, wiring lines can be formed in a high density on the core substrate and wiring lines can be extended on the through hole. Consequently, the double-sided wiring board has less layers and wiring lines formed in a higher density than the conventional double-sided wiring board.

The present invention forms a through hole in the core substrate by laser machining. The laser machining machine is capable of accurate positioning. Therefore, a margin for the diameter of lands to allow for errors in the positions of lands and through hole can be reduced, through hole can be formed in small diameter, and lands can be formed in diameters not greater than 250 μm.

Since a practical method of securing adhesive strength between a resin layer and wiring lines has been elucidated, a semiadditive method can be employed.

Both the surfaces of the core substrate, i.e., an insulating resin film, can be roughened in a desired roughness by transferring the shape of a roughened surface of an electroplated Cu layer to the surfaces of the core substrate.

Thus, wiring lines having the smallest width of 20 μm can be formed at a line spacing of 20 μm can be formed on the double-sided wiring board of the present invention.

The double-sided wiring board fabricating method of the present invention forms wiring lines on both the surfaces of a core substrate, electrically connects the wiring lines formed on both the surfaces of the core substrate by means of the through hole filled up with a conductive plug formed by plating, and forms solder resist layers on both the surfaces of the core substrate so that predetermined terminals are exposed. The through hole formed in the core substrate is filled up with a conductive plug formed by plating. The wiring lines are formed on the core substrate by a semiadditive method.

Thus, the double-sided wiring board fabricating method is capable of fabricating a double-sided wiring board suitable for high-density packaging and excellent, as compared with the conventional buildup multilayer wiring board, in productivity and quality.

More specifically, the double-sided wiring board fabricating method of the present invention transfers the shape of the roughened surface of an electrolytic Cu foil to both the surfaces of a core substrate formed of an insulating resin to obtain a core substrate having desired roughened surfaces. The wiring lines formed by the semiadditive method ensures sufficient adhesive strength between the core substrate and the wiring lines.

The method of forming the roughened surfaces of the core substrate is subject to few restrictions in respect of applicable materials, and the insulating resin forming the core substrate can be selected from a large variety of resins.

The taper through hole is formed in the core substrate by laser machining. The taper through hole facilitates filling up the through hole with a conductive plug by plating, and a surface of a region corresponding to the through hole can be formed in a satisfactory flatness.

The electroplated Cu layer is planarized by mechanical or chemical-mechanical polishing before or after removing unnecessary parts of the electroless-plated layer by flash etching, before or after removing a resist pattern used by a selective plating process. Thus, the surfaces of wiring lines and pads, and a plug formed in the through hole formed by a selective plating process are planarized. More concretely, deviations of the surfaces of the wiring lines the pads and the plug from a reference plane are limited to a range of ±5 μm.

The wiring lines and the pads formed by the selective plating process have an outward convex, round sectional shape. The wiring lines and the pads can be shaped in a substantially rectangular sectional shape. The dented end surface of the plug formed in the through hole by plating can be flattened.

The surfaces of the double-sided wiring board can be finished by mechanical or chemical-mechanical polishing such that semiconductor chips do not slip easily when the same are mounted on the double-sided wiring board by wire bonding or flip-chip solder bonding, the depth of dents can be reduced, and the wiring lines are formed in uniform thickness.

If the surfaces are not finished by mechanical or chemical-mechanical polishing, wiring lines 910, terminals (pads) 920 have outward convex, round sectional shapes as shown in FIGS. 10(a), 10(b) and 10(c). In some cases, through hole parts 930 including lands have dented surfaces. The surfaces of the wiring lines 910, the terminals (pads) 920 and the through hole parts 930 are planarized as shown in FIGS. 10(a1), 10(b1) and 10(c1) by mechanical or chemical-mechanical polishing.

Wiring lines is the general term for terminals, lands and connecting lines in this specification. The term “wiring lines” will be used to name generally connecting lines, terminals and lands.

The double-sided wiring board fabricating method of the present invention is capable of forming a through hole region having lightly dented surface, the slightly dented surface of the through hole region can be planarized by mechanical or chemical-mechanical polishing, and flat solder resist layers can be formed on both the surfaces of the double-sided wiring board. When semiconductor chips are mounted on a double-sided wiring board fabricated by this double-sided wiring board fabricating method, bubble inclusion that spoils the reliability of semiconductor devices does not occur between the semiconductor chips and the double-sided wiring board. Consequently, load on processes can be reduced.

The double-sided wiring board of the present invention thus constructed is suitable for high-density packaging, and is excellent, as compared with the conventional buildup multilayer wiring board, in productivity and packaging.

Specifically, the through hole is formed in a diameter not greater than 150 μm in the core substrate by laser machining.

Naturally, the through hole may be formed in a diameter greater than 150 μm.

The through hole formed in the core substrate by laser machining may be a taper through hole having a trapezoidal cross section and tapered from one side of the core substrate from which a laser beam falls on the core substrate toward the other side of the core substrate. Such a taper through hole facilitate filling up the through hole with a solder resist. Satisfactorily flat solder resist layers can be formed on both the surfaces of the wiring board including the through hole region. Forming the through hole in the core substrate by laser machining facilitates work for fabricating the double-sided wiring board having surfaces of excellent quality.

The through hole of the conventional core substrate formed by mechanical drilling cannot be formed in a diameter not greater than 150 μm.

Both the surfaces of the core substrate are roughened to enable formation of wiring lines by the semiadditive method. The semiadditive method is capable of forming fine wiring lines in a high density.

Thus, when the double-sided wiring board is used for forming a semiconductor IC package, wiring lines can be arranged in an arrangement in which wiring lines cannot be arranged when a core substrate as shown in FIG. 7(d) is used as an interposer for a semiconductor IC package. The double-sided wiring board of the present invention can be used instead of a buildup multilayer wiring board provided with at least one buildup layer.

It is preferable that both the roughened surfaces of the core substrate have a ten-point height irregularity Rz (JIS) in the range of 2 to 10 μm.

The adhesion of the wiring lines to the surfaces of the core substrate is not sufficient when the surface roughness Rz (JIS) is smaller than 2 μm, and irregularities in the surfaces of the core substrate affect adversely to the shape of wiring lines, hinder the miniaturization of wiring lines and increases load on the manufacture of the electrolytic Cu foils when the surface roughness Rz (JIS) is greater than 10 μm.

Naturally, the double-sided wiring board of the present invention is superior in productivity to the conventional buildup multilayer wiring board.

A double-sided wiring board according to the present invention has one surface provided with connection pads to mount a semiconductor chip on the same surface by flip-chip solder bonding or wire bonding, and the other surface provided with terminals to which external circuits are to be connected. Generally, the terminals a coated with a plated Ni layer and a plated Au layer formed in that order.

The present invention forms a through hole in the core substrate by laser machining. The laser machining machine is capable of accurate positioning. Therefore, a margin for the diameter of lands to allow for errors in the positions of lands and a through hole can be reduced, a through hole can be formed in a small diameter, and lands can be formed in diameters not greater than 250 μm.

Since a practical method of securing adhesive strength between a resin layer and wiring lines has been elucidated, a semiadditive method can be employed.

Both the surfaces of the core substrate, i.e., an insulating resin film, can be roughened in a desired roughness by transferring the shape of a roughened surface of an electrolytic Cu foil to the surfaces of the core substrate.

Thus, wiring lines having the smallest width of 20 μm can be formed at a line spacing of 20 μm can be formed on the double-sided wiring board of the present invention.

The double-sided wiring board fabricating method of the present invention forms wiring lines on both the surfaces of a core substrate, electrically connects the wiring lines formed on both the surfaces of the core substrate by means of a through hole filled up with a conductive plug, and forms solder resist layers on both the surfaces of the core substrate so that predetermined terminals are exposed. The through hole is formed in the core substrate by laser machining and a surface of the through hole is plated. The through hole is filled up with the solder resist. The wiring lines are formed by a semiadditive method.

Specifically, the shape of the roughened surfaces of an electrolytic Cu foil is transferred to both the surfaces of a core substrate formed of an insulating resin to roughen the surfaces in a desired roughness. Wiring lines are formed by a semiadditive method.

The through hole formed in the core substrate by laser machining is a taper through hole having a trapezoidal cross section. Such a taper through hole facilitates filling up the through hole with a plug by plating. The through hole is filled up with the solder resist. The surface of a through hole region can be formed in a satisfactory flatness.

The insulating resin forming the core substrate can be selected from a large variety of resins.

Thus, the double-sided wiring board fabricating method is capable of fabricating a double-sided wiring board suitable for high-density packaging and excellent, as compared with the conventional buildup multilayer wiring board, in productivity.

According to the present invention, a multilayer wiring board comprises a double-sided wiring board which includes a core substrate having two roughened surfaces and wiring layers formed on both the surfaces of the core substrate, respectively, the wiring layers being electrically connected through a through hole formed in the core substrate; and an additional wiring board formed on one side of the double-sided wiring board through an insulating resin layer; wherein the additional wiring layer includes an additional core substrate having two roughened surfaces and additional wiring layers formed on both the surfaces of the additional core substrate, and the additional wiring layers are electrically connected through an additional through hole formed in the additional core substrate.

In the multilayer wiring board according to the present invention, the double-sided wiring board and the additional wiring board are connected to each other through a bump.

In the multilayer wiring board according to the present invention, the bump is positioned at a portion corresponding to the through hole of the double-sided wiring board.

In the multilayer wiring board according to the present invention, a conductive plug is formed in the through hole of the double-sided wiring board by filling up the through hole with a conductive material.

According to the present invention, a multilayer wiring board includes a double-sided wiring board having two roughened surfaces and wiring layers formed on both surfaces of the core substrate, respectively, the wiring layers being electrically connected through a through hole formed in the core substrate; and additional wiring layers formed on both the sides of the double-sided wiring layer through insulating resin layers.

In the multilayer wiring board according to the present invention, the additional insulating resin layers are formed on the respective additional wiring layers so as to expose additional terminals.

### BRIEF DESCRIPTION OF THE DRAWINGS

FIG. 1(a) is a fragmentary sectional view of a double-sided wiring board in a first embodiment according to the present invention;

FIG. 1(b) is a double-sided wiring board in a modification of the first embodiment shown in FIG. 1(a);

FIGS. 2(a) to 2(g) are sectional views of assistance in explaining steps of a double-sided wiring board fabricating method of fabricating the double-sided wiring board in the first embodiment shown in FIG. 1(a);

FIGS. 3(a) to 3(d) are sectional views of assistance in explaining steps subsequent to those shown in FIGS. 2(a) to 2(g);

FIGS. 4(a) to 4(f) are sectional views of assistance in explaining steps of a double-sided wiring board fabricating method of fabricating a double-sided wiring board in a comparative example;

FIGS. 5(a) to 5(g) are sectional views of assistance in explaining steps subsequent to those shown in FIGS. 4(a) to 4(f);

FIGS. 6(a) to 6(d) are sectional views of assistance in explaining steps subsequent to those shown in FIGS. 5(a) to 5(g);

FIGS. 7(a) to 7(d) are sectional views of assistance in explaining steps of a conventional core substrate fabricating method;

FIG. 8 is a schematic sectional view of a conventional multilayer wiring board;

FIG. 9 is a schematic sectional view of a semiconductor IC package employing a multilayer wiring board;

FIGS. 10(a) to 10(c) are sectional views of wiring lines, terminals and a through hole part before mechanical polishing;

FIGS. 10(a1) to 10(c1) are schematic sectional views of the wiring lines, the terminals and the through hole part, respectively corresponding to those shown in FIGS. 10(a) to 10(c), after mechanical polishing;

FIG. 11(a) is a fragmentary sectional view of a double-sided wiring board in a second embodiment according to the present invention;

FIG. 11(b) is a fragmentary sectional view of a double-sided wiring board in a modification of the second embodiment shown in FIG. 11(a);

FIGS. 12(a) to 12(g) are sectional views of assistance in explaining steps of a double-sided wiring board fabricating method of fabricating the double-sided wiring board in the second embodiment shown in FIG. 11(a);

FIGS. 13(a) to 13(d) are sectional views of assistance in explaining steps subsequent to those shown in FIGS. 12(a) to 12(g);

FIGS. 14(a) to 14(f) are sectional views of assistance in explaining steps of a double-sided wiring board fabricating method of fabricating a double-sided wiring board in a comparative example;

FIGS. 15(a) to 15(d) are sectional views of assistance in explaining steps subsequent to those shown in FIGS. 14(a) to 14(f);

FIG. 16 is a through hole in a modification formed on the core substrate;

FIG. 17 is a multilayer wiring board according to the present invention; and

FIG. 18 is another multilayer wiring board.

### BEST MODE FOR CARRYING OUT THE INVENTION

### First Embodiment

A first embodiment of the present invention will be described with reference to the accompanying drawings.

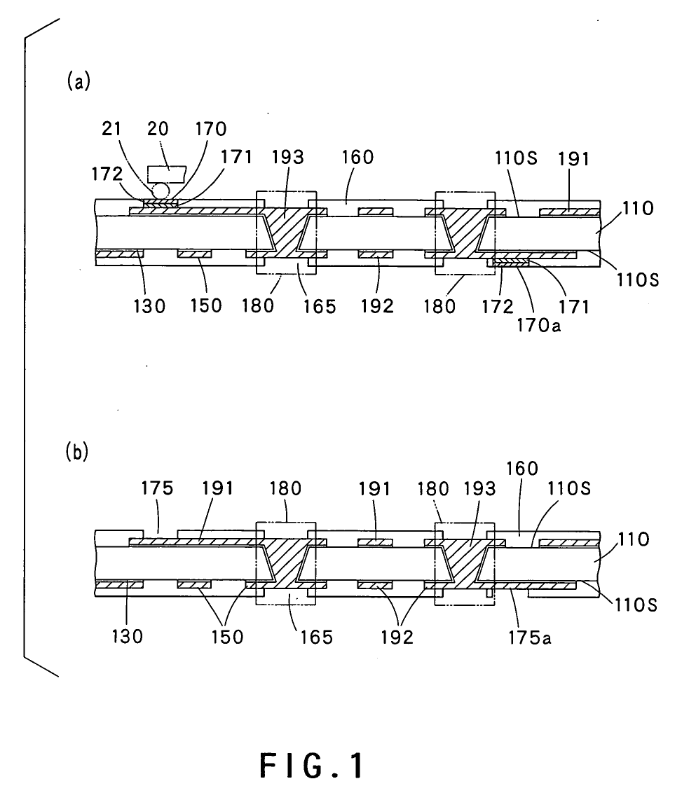

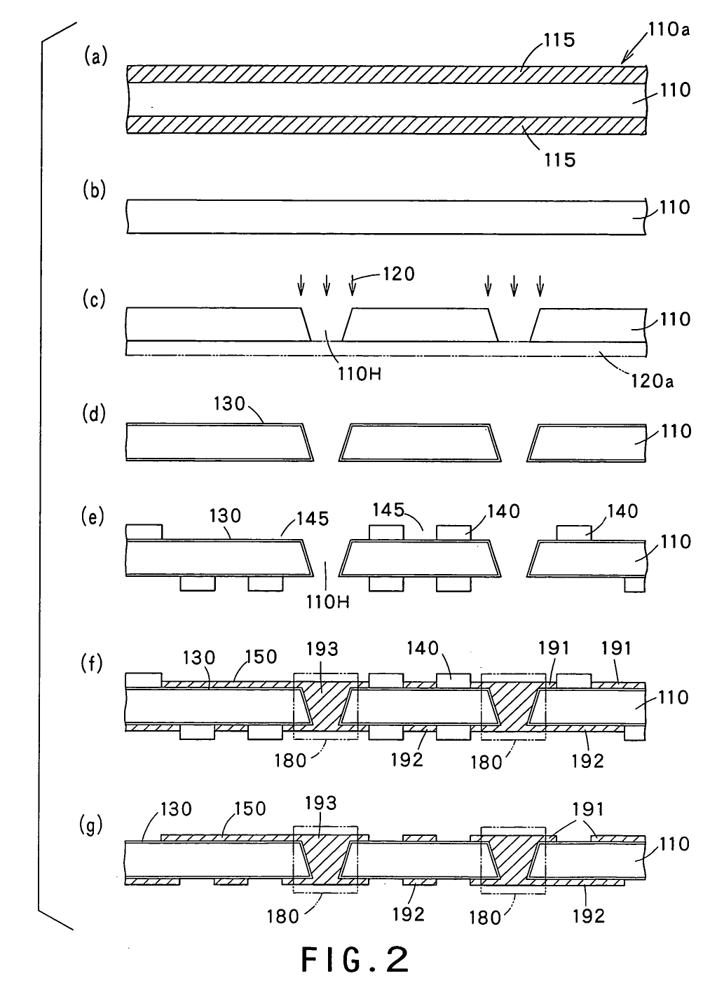

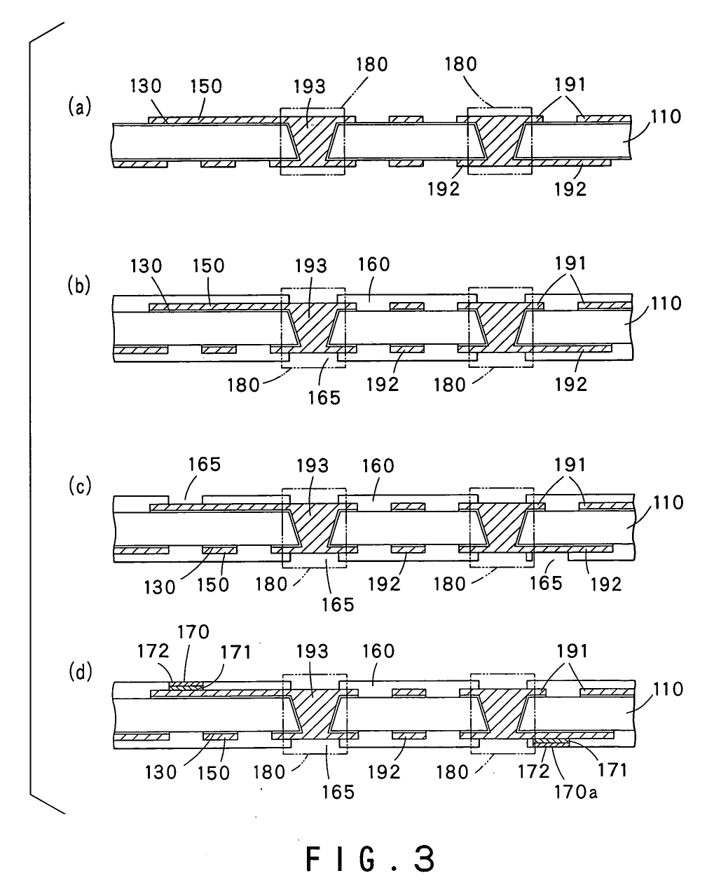

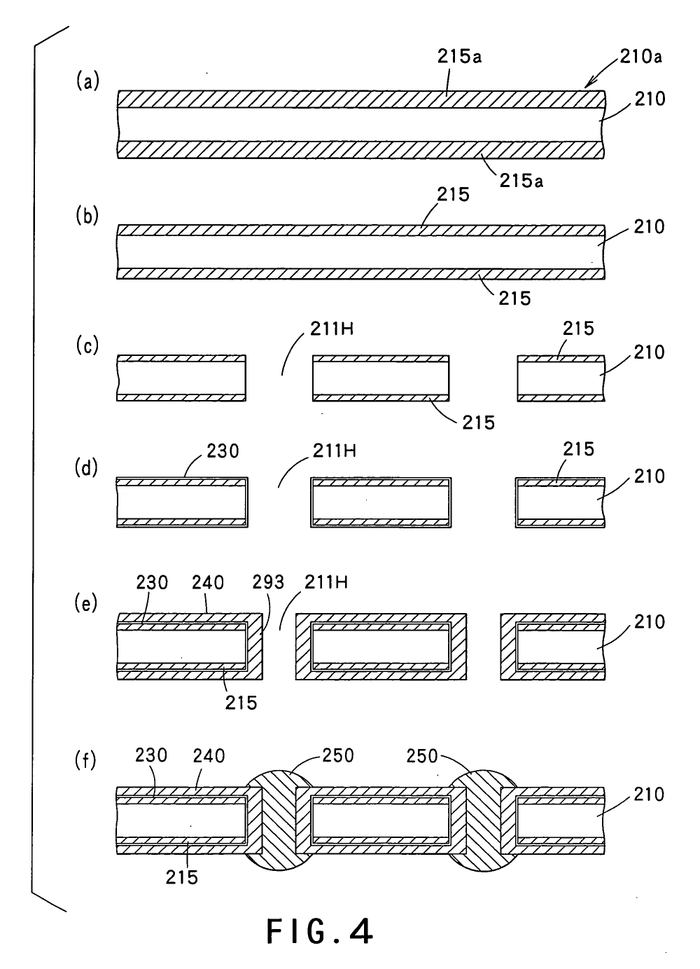

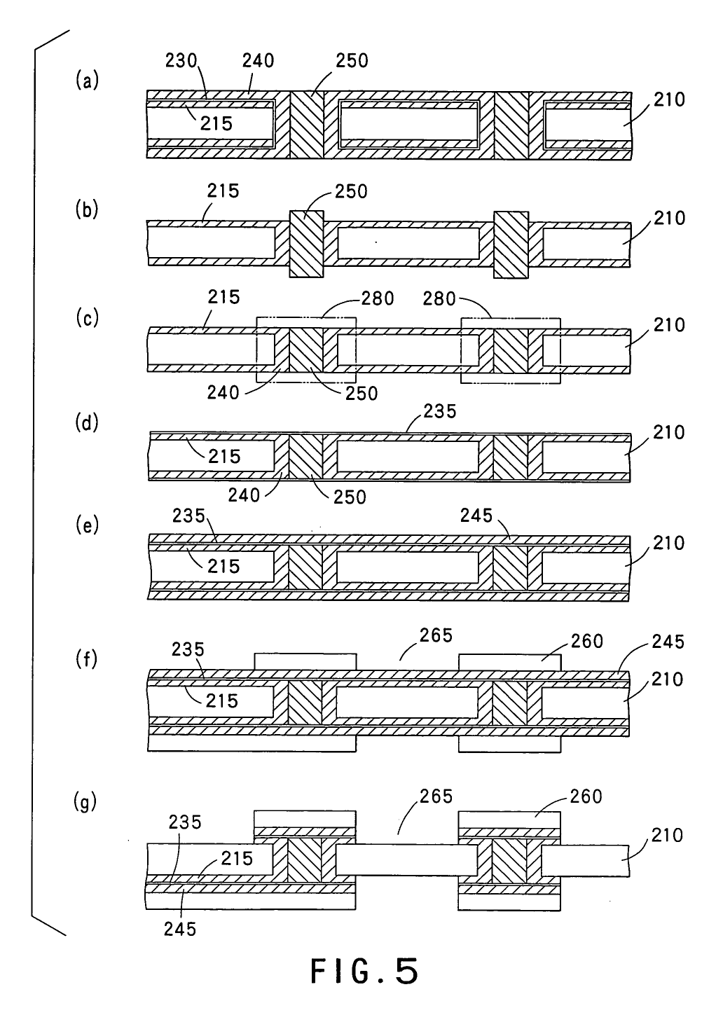

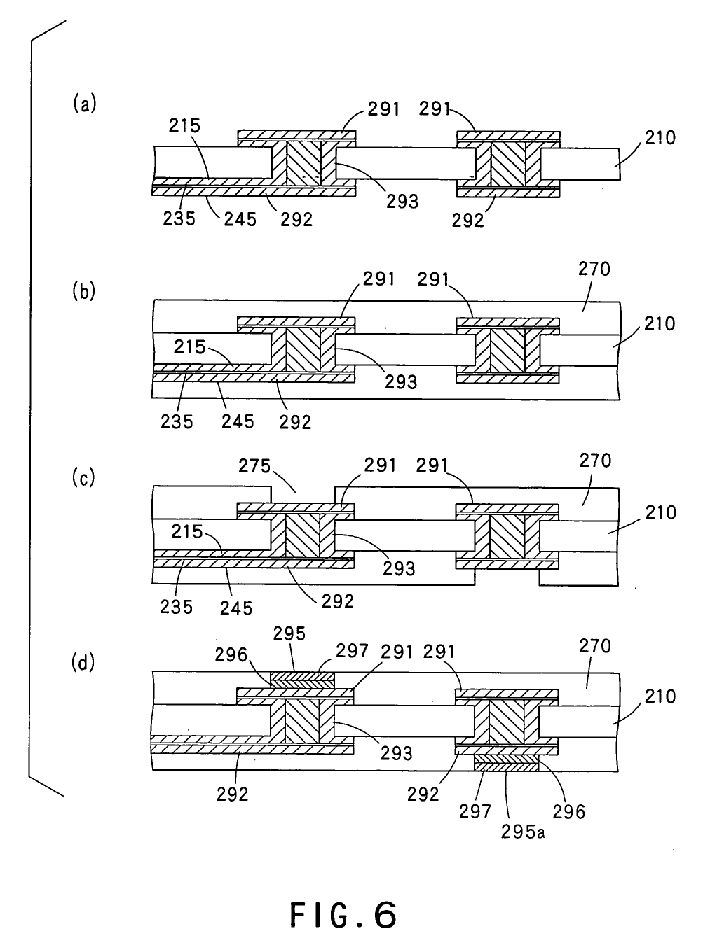

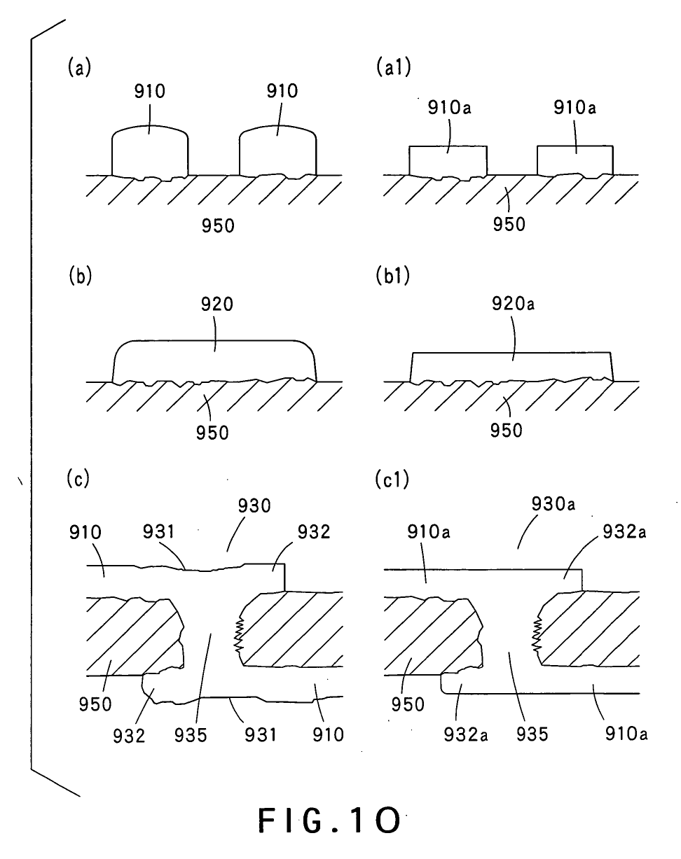

FIG. 1(a) is a fragmentary sectional view of a double-sided wiring board in a first embodiment according to the present invention, FIG. 1(b) is a double-sided wiring board in a modification of the first embodiment shown in FIG. 1(a), FIGS. 2(a)-2(g) are sectional views of assistance in explaining steps of a double-sided wiring board fabricating method of fabricating the double-sided wiring board in the first embodiment shown in FIG. 1(a), FIGS. 3(a)-3(d) are sectional views of assistance in explaining steps subsequent to those shown in FIGS. 2(a)-2(g), FIGS. 4(a)-4(f) are sectional views of assistance in explaining steps of a double-sided wiring board fabricating method of fabricating a double-sided wiring board in a comparative example, FIGS. 5(a)-5(g) are sectional views of assistance in explaining steps subsequent to those shown in FIGS. 4(a)-4(f), FIGS. 6(a)-6(d) are sectional views of assistance in explaining steps subsequent to those shown in FIGS. 5(a)-5(g), and FIGS. 10(a)-10(c) are sectional views of parts of assistance in explaining mechanical polishing, in which FIGS. 10(a) to 10(c) are sectional views of parts before mechanical polishing, and FIGS. 10(a1) to 10(c1) are schematic sectional views of parts respectively corresponding to those shown in FIGS. 10(a) to 10(c), after mechanical polishing.

Shown in FIGS. 1(a) and 1(b) to 6(a)-6(d) and 10(a)-10(c) are a core substrate 110, a through hole 110H, surfaces 110S of the core substrate 110, electrolytic Cu foils 115, a laser beam 120, electroless-plated layers 130, resist layers 140, open areas 145, electroplated Cu layers 150, solder resist layers 160, open areas 165, chip bond pads (referred to also as inner terminals) 170, outer pads (referred to also as outer terminals) 170a, a plated Ni layer 171, a plated Au layer 172, terminal parts 175 and 175a, connecting parts 180, wiring layers 191 and 192, a conductive plug 193, a core substrate 210, a through hole 211H, electrolytic Cu foils 215a, thin electrolytic Cu foils 215 formed by etching the electrolytic Cu foils 215a, electroless-plated layers 230 and 235, electroplated Cu layers 240 and 245, insulating ink plugs (resin ink plugs) 250, resist layers 260, open areas 265, solder resist layers 270, open areas 275, connecting parts 280, wiring lines 291 and 292, conductive plugs 293, terminals 295 and 295a, plated Ni layers 296, plated Au layers 297, connection lines 910 and 910a, terminals (referred to also as pads) 920 and 920a, through hole parts 930 and 930a, dents 931, lands 932 and 932a, conductive plugs 935 and insulating substrate 950.

A double-sided wiring board in a first embodiment according to the present invention will be described with reference to FIG. 1(a).

The double-sided wiring board of the present invention includes a core substrate 110 having opposite roughened surfaces 110S, and wiring layers 191 and 192 formed on the surfaces 110S of the core substrate 110. The double-sided wiring board is fabricated by a double-sided wiring board fabricating method illustrated in FIGS. 2(a)-2(g) and 3(a)-3(d). Wiring layers having wiring layers 191 and 192 are formed by a semiadditive method respectively on the roughened surfaces 111S of the core substrate 110. The wiring layers 191 and 192 are electrically connected by connecting parts 180 consisting of the through hole 110 of the core substrate 110. The predetermined inner terminals 170 and predetermined outer terminals 170a are connected to the wiring layers 191 and 192. Solder resist layers 160 are formed on both the surfaces of the core substrate 110 such that the terminals 170 and 170a are exposed. The double-sided wiring board is used for fabricating a semiconductor IC package. The double-sided wiring board replaces the multilayer wiring board 10 used as an interposer in the semiconductor IC package shown in FIG. 9.

Each connecting part 180 is formed by forming the through hole 110H in the core substrate 110 by laser machining, and filling up the through hole 110H with a conductive plug 193 by plating. The open areas 165 of the solder resist layers 160 are formed so as to correspond to the conductive plug 193.

The chip bond pads (inner terminals) 170 are formed on the surface provided with the wiring layers 191 of the core substrate 110. A semiconductor chip 20 is mounted on the double-sided wiring board and the solder bumps 21 of the semiconductor chip are connected to the chip bond pads 170 by flip-chip solder bonding or wire bonding. The outer terminals 170a are formed on the other surface provided with the wiring layers 192 of the core substrate 110. The outer terminals 170a are connected to external circuits.

Naturally, the chip bond pads 170 and the outer terminals 170a may be selectively formed respectively on the opposite surfaces of the core substrate 110.

Each of the chip bond pads 170 and the outer terminals 170a has the electroplated Cu layer 150 formed on the electroless-plated layer 130, and a laminate structure formed on the electro-plated Cu layer 150 so as to fill up an opening in the solder resist layer 160 and including the plated Ni layer 171 and the plated Au layer 172 formed on the plated Ni layer 171.

The surfaces 110S of the core substrate 110 have a ten-point height irregularity Rz (JIS) in the range of 2 to 10 μm. When the surfaces 110S of the core substrate 110 have a ten-point height irregularity Rz in this specified range, adhesive strength between the surfaces 110S and the wiring layers 191 and 192 is high, and the wiring layers 191 and 192 can be accurately formed. Formation of surfaces having such a ten-point height irregularity is practically feasible.

The core substrate 110 is formed by impregnating a fabric, such as glass cloth, nonwoven aramide cloth, nonwoven liquid crystal polymer cloth or porous polytetrafluoroethylene cloth (such as Gore Tex®), with an insulating, heat-resistant, thermosetting resin.

Suitable insulating, heat-resistant, thermosetting resins are cyanate resins, BT resins (bismaleimide-triazine resins), epoxy resins and PPE resins (polyphenylene ether resins).

Peel strength of a wiring layer formed on a film of a cyanate resin of 679F Series (Hitachi) having surfaces of a ten-point height irregularity Rz of 5 μm as the core substrate 110 measured by a peel strength test method specified in C5012, JIS, Aug. 1, 1987 was 800 g/cm.

The surfaces 110S of the resin core substrate 110 are formed by bonding electrolytic Cu foils 115 (FIG. 2) to the core substrate 110 by thermocompression bonding with the plated surfaces of the electrolytic Cu foils 115 in contact with the core substrate 110. The shapes of the roughened plated surfaces of the electrolytic Cu foils 115 are transferred to the surfaces 110S of the core substrate 110 (FIGS. 2 and 3) to enhance adhesive strength between the surfaces 110S of the core substrate 110, and the wiring layers 191 and 192.

The connecting parts 180 are formed in parts, provided with the through holes 110H formed by laser machining, of the core substrate 110. Generally, laser machining uses a CO₂ laser or a UV laser. The diameter of the through holes 110H is 150 μm or below.

The electroplated Cu layers 150 forming the wiring layers 191 and 192 and the conductive plug 193 of the through holes are formed by a known blind via filling plating method.

Preferably, the thickness of the wiring layers 191 and 192 is in the range of about 5 to about 30 μm, in view of conductivity. Supposing that the core substrate 110 has a thickness of 100 μm, the diameter of one end, on the side from which a laser irradiates the core substrate 110, of each of the through holes 110H has a diameter of 100 μm, and the other end of each of the through holes 110H has a diameter of 70 μm, the thickness of the wiring lines 191 and 192, in general, is in the range of about 10 to about 30 μm.

The electroless-plated layers 130 are formed by a known electroless Ni or Cu plating process. The electroless-plated layers 130 serve as plating electrodes for forming the electroplated Cu layers 150 for forming the wiring layers 191 and 192, and the conductive plug 193. The electroless-plated layers 130 have a predetermined thickness that permits the electroless-plated layers 130 to be easily removed by flash etching without damaging other parts.

FIG. 1(b) shows a double-sided wiring board similar to the double-sided wiring board shown in FIG. 1(a), except that the former does not have any terminals corresponding to the terminals 170 and 170a each consisting of the plated Ni layer 171 and the plated Au layer 172 of the latter. In some cases, the double-sided wiring board shown in FIG. 1(b) is shipped as it is.

Parts included in the double-sided wiring board shown in FIG. 1(b) are the same as those of the double-sided wiring board shown in FIG. 1(a), and hence the description thereof will be omitted.

A double-sided wiring board fabricating method of fabricating the double-sided wiring board shown in FIG. 1(a) will be described in connection with FIGS. 2(a)-2(g) and 3(a)-3(d).

This description shall be considered to be the description of a double-sided wiring board fabricating method embodying the present invention.

A three-layer laminated workpiece 110a shown in FIG. 2(a) is formed by bonding electrolytic Cu foils 115 each having a roughened surface to the opposite surfaces of an insulating resin film for forming a core substrate 110 with the roughened surfaces thereon by compression bonding.

The electrolytic Cu foils 115 are bonded to the opposite surfaces of the insulating resin film with layers of a thermosetting resin by thermocompression bonding, with the plated, roughened surfaces of the electrolytic Cu foils 115 being in contact with the insulating resin film.

The insulating resin film is produced by impregnating a fabric, such as glass cloth, nonwoven aramide cloth, nonwoven liquid crystal polymer cloth or porous polytetrafluoroethylene cloth (such as Gore Tex®), with an insulating resin.

Suitable insulating resins are cyanate resins, BT resins (bismaleimide-triazine resins), epoxy resins and PPE resins (polyphenylene ether resins).

Subsequently, the electrolytic Cu foils 115 are removed from the surfaces of the insulating resin film by etching to obtain the core substrate 110 having surfaces 110S of a shape formed by transferring the shape of the surfaces of the electrolytic Cu foils 115 as shown in FIG. 2(b).

A ferric chloride solution, a cupric chloride solution or an alkaline etching solution is used for etching the electrolytic Cu foils 115.

The core substrate 110 is cleaned, and then through holes 110H are formed in the core substrate 110 by irradiating parts of the core substrate 110 selectively with a laser beam 120 as shown in FIG. 2(c).

The laser beam 120 is emitted by a CO₂ laser or a UV laser depending on the quality of the materials of the core substrate 110.

The through holes 110H are formed in the core substrate 110 by placing a plate 120a that does not excessively reflect a laser beam 120, such as a black plate, on one of the surfaces of the core substrate 110, and irradiating the core substrate 110 from the side of the other surface of the core substrate 110 with the laser beam 120. The through holes 110H formed in the core substrate 110 by laser machining may have a trapezoidal cross section and tapered from one side of the core substrate from which the laser beam 120 falls on the core substrate 110 toward the other side of the core substrate.

When the core substrate 110 contains a cyanate resin and has a thickness of 100 μm and the through holes 110H are formed by laser machining using a CO₂ laser, each of the through holes 110H has a large end of a diameter of 100 μm and a small end of a diameter of 70 μm.

The taper through holes 110H facilitate filling up the through holes 110H with an electroplated layer 150. Solder resist layers 160 are formed on the opposite surfaces of the core substrate 110 after planarizing through hole regions corresponding to the through holes 110H.

Through holes of the conventional core substrate are formed by mechanical drilling. It is difficult to form the through holes in a diameter below 150 μm. According to the present invention, the through holes 110H of a diameter not greater than 150 μm can be formed in the core substrate 110 by laser machining.

The minimum possible diameter of the through holes 110H is 80 μm when a CO₂ laser is used for laser machining or about 25 μm when a UV-YAG laser is used for laser machining.

The core substrate 110 is subjected to a desmearing process to remove residual chips produced by laser machining before forming the electroless-plated Cu layers. Then, the core substrate 110 is subjected to electroless plating to plate the core substrate entirely with electroless-plated layers 130 as shown in FIG. 2(d).

The electroless-plating of the core substrate 110 can be achieved by a known Cu or Ni electroless plating process.

Then, resist layers 140 are formed on both the surfaces of the core substrate 110. The resist layers 140 are provided with openings 145 corresponding to regions in which wiring layers 191 and 192, and conductive plugs 193 included in connecting parts 180 are to be formed as shown in FIG. 2(e).

Then, electroplated Cu layers 150 are formed by Cu electroplating using the electroless-plated layers 130 as plating electrodes to form the wiring layers 191 and 192, and the conductive plugs 193 filling up the through holes 110H as shown in FIG. 2(f).

Since the electroless-plated layers 130 formed by a known plating process, such as a Cu or Ni electroless plating process serve only as plating electrodes for forming the electroplated Cu layers 150 for forming the wiring layers 191 and 192, the electroless-plated layers 130 may be formed in a predetermined thickness that permits the electroless-plated layers 130 to be easily removed by flash etching without damaging other parts.

The resist layers 140 may be formed of any type of resist, provided that the resist layers 140 can be patterned in a desired resolution, and is resistant to plating actions and satisfactory in workability.

Usually, dry resist films are used as the resist layers 140 because dry resist films are easy to handle.

Then, the resist layers 140 are removed (FIG. 2(g)), and exposed, unnecessary parts of the electroless-plated layers 130 are removed by flash etching as shown in FIG. 3(a).

Suitable etching solutions for flash etching include mixture of sulfuric acid with hydrogen peroxide solutions, persulfuric acid solutions, hydrochloric acid solutions, nitric acid solutions, cyanide solutions and organic etching solutions.

A photosensitive solder resist is applied to both the surfaces of the core substrate 110 to form solder resist layers 160 on both the surfaces of the core substrate 110 as shown in FIG. 3(b).

Subsequently, the solder resist layers 160 are exposed through a predetermined photomask, the exposed solder resist layers 160 are developed to expose areas corresponding to chip bond pads 170 and outer pads 170a as shown in FIG. 3(c).

Subsequently, the chip bond pads 170 and the outer pads 170a are formed as shown in FIG. 3(d) by depositing a plated Ni layer 171 and a plated Au layer 172 in that order on the surfaces of the exposed areas corresponding to the chip bond pads 170 and the outer pads 170a to complete the double-sided wiring board in the first embodiment.

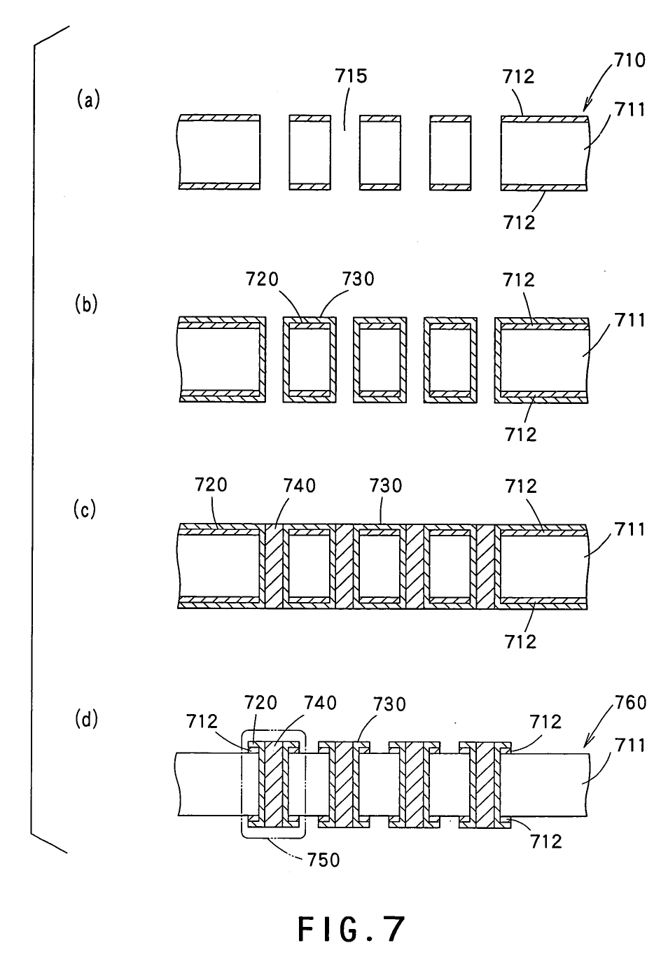

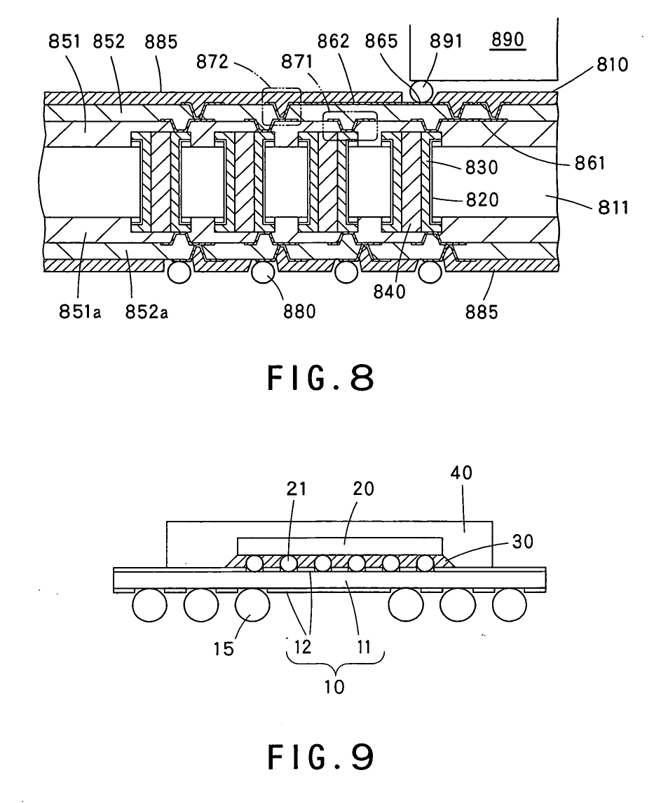

A double-sided wiring board in a comparative example comparing with the double-sided wiring board shown in FIG. 1(a) will be described. The double-sided wiring board in a comparative example has a core substrate provided, similarly to the conventional core substrate shown in FIG. 7, with wiring layers formed on both the surfaces, and through holes formed by mechanical drilling and having plated side surfaces connecting wiring lines formed by processing the wiring layers. The through holes of the core substrate are filled up with an insulating ink (resin ink), and the wiring lines formed on both the surfaces of the core substrate are coated with solder resist layers. The double-sided wiring board in a comparative example for a semiconductor IC package will be described with reference to FIGS. 4 to 6.

A three-layer laminated workpiece 210a similar to that shown in FIG. 2(a) is fabricated by bonding electrolytic Cu foils 215a to both the surfaces of a core substrate 210 by thermocompression bonding as shown in FIG. 4(a). Then, the electrolytic Cu foils 215a bonded to both the surfaces of the core substrate 210 are thinned in a desired thickness by etching as shown in FIG. 4(b). Subsequently, through holes 211H are formed in the workpiece 210a as shown in FIG. 4(c) by mechanical drilling. The workpiece is subjected to a polishing process to remove flashes, and to a desmearing process for cleaning. Then, electroless-plated layers 230 are formed on the workpiece 210a by electroless plating as shown in FIG. 4(d). Then, electroplated Cu layers 240 are formed on both the surfaces of the core substrate 210, and conductive layers 293 are formed on the side surfaces of the through holes 211H as shown in FIG. 4(e) by Cu electroplating using the electroless-plated layers 230 as plating electrodes.

Subsequently, the through holes 211H are filled up with a thermosetting insulating ink from both the surfaces or one of the surfaces of the core substrate 210 (resin ink), the thermosetting insulating ink filling up the through holes 211H are cured by heating to form insulating ink plugs 250 in the through holes 211H as shown in FIG. 4(f).

Then, end parts, protruding from the surfaces of the electroplated Cu layers 240, of the insulating ink plugs 250 are removed by grinding as shown in FIG. 5(a). Then, the electroplated layers 240 and the electroless-plated layers 230 are removed by half etching from the surfaces of the core substrate 210 as shown in FIG. 5(b). Then, end parts, projecting from the thin electrolytic Cu foils 215, of the insulating ink plugs 250 are removed by grinding to planarize the surfaces of the workpiece 210a as shown in FIG. 5(c).

Subsequently, electroless-plated layers 235 are formed on both the surfaces of the core substrate 210 by electroless plating as shown in FIG. 5(d), and electroplated Cu layers 245 of a predetermined thickness corresponding to that of wiring layers are formed on the electroless-plated layers 235 by Cu electroplating as shown in FIG. 5(e).

Then, resist layers 260 resistant to etching and provided with openings 265 in predetermined parts thereof are formed on both the surfaces of the core substrate 210 as shown in FIG. 5(f). Parts of the electroplated Cu layers 245 and the electroless-plated layers 235 and the thin electrolytic Cu foils 215 corresponding to the openings 265 of the resist layers 260 are removed by etching using an etchant, such as a ferric chloride solution, as shown in FIG. 5(g). Then, the resist layers 260 are removed as shown in FIG. 6(a). Then, solder resist layers 270 of a photosensitive solder resist are formed on both the surfaces of the core substrate 210 as shown in FIG. 6(b).

Then, openings are formed in parts, corresponding to terminal forming areas 275, of the solder resist layers 270 by photolithography as shown in FIG. 6(c). A plated Ni layer 296 and a plated Au layer 297 are formed in that order on exposed parts of the electroplated Cu layers 245. Thus, the double-sided wiring board in a comparative example as shown in FIG. 6(d) is completed.

This double-sided wiring board fabricating method forms the wiring layers by etching the thin electrolytic Cu foils 215, the electroless-plated layers 235 and the electroplated Cu layers 245, which are previously prepared. Thus, this double-sided wiring board fabricating method forms the wiring layers by processes basically similar to those of the method illustrated in FIG. 7 that uses principally a subtractive method that etches wiring layers. Therefore, it is unable to cope with the miniaturization of wiring lines and the increase of packaging density.

Therefore, it is difficult to fabricate a double-sided wiring board provided with wiring layers of a width on the order of 50 μm or less arranged at line spacing on the order of 50 μm or less by this method.

The through holes 211H formed on the core substrate 210 by mechanical drilling have a large diameter. Therefore, the core substrate, similarly to the conventional core substrate shown in FIG. 7(d), cannot be provided with through holes of a diameter below 150 μm and lands of a diameter below 350 μm.

The fabrication of the buildup multilayer wiring board needs many complicated processes, the cost for fabricating the buildup multilayer wiring board is high, the through holes cause large power loss, and the buildup multilayer wiring board is unsuitable for uses that need to deal with high-frequency signals.

The double-sided wiring board in a comparative example has the foregoing problems and is unsuitable for high-density packaging.

A double-sided wiring board in a modification of the double-side wiring board embodying the present invention will be described.

Referring to FIGS. 1 to 3, end surfaces of conductive plugs 193 formed in through holes 110H formed in a core substrate 110 and the surfaces of wiring layers 191 and 192 formed on the surfaces of the core substrate 110 of a double-sided wiring board in a modification are planarized by mechanical or chemical-mechanical polishing.

Since the end surfaces of the conductive plugs 193 formed in the through holes 110H, and the surfaces of the wiring layers 191 and 192 of the double-sided wiring board are planarized by mechanical or chemical-mechanical polishing, semiconductor chips rarely slide when the semiconductor chips are mounted on the double-sided wiring board by wire bonding or flip-chip solder bonding, the conductive plugs 193 filling up the through holes 110H do not have any dents, and the wiring layers 191 and 192 have a uniform thickness.

The double-sided wiring board is particularly effective when the same is used to form a semiconductor IC package.

Referring to FIGS. 2 and 3, in a double-sided wiring board fabricating method in a modification of the foregoing double-sided wiring board fabricating method, electroplated Cu layers 150 formed by a selective plating process are planarized by mechanical or chemical-mechanical polishing at a stage corresponding to a stage shown in FIG. 2(f), before removing patterned resist layers after the completion of a selective plating process, at a stage corresponding to a stage shown in FIG. 2(g), before removing unnecessary parts of electroless-plated layers by flash etching after removing patterned resist layers or at a stage corresponding to a stage shown in FIG. 3(a), after removing unnecessary parts of the electroless-plated layers by flash etching. The double-sided wiring board fabricating method in a modification, excluding the polishing step, is the same as the foregoing double-sided wiring board fabricating method and hence further description thereof will be omitted.

The mechanical polishing consists of, for example, buffing. Recently, chemical-mechanical polishing (CMP) is often applied to various processes.

The electroplated Cu layers 150 are planarized in a flatness in the range of ±0.5 μm

The terminal point of polishing can be determined by a method that measures torque or a method that measures electrostatic capacity.

In a double-sided wiring board in a modification, the plated Ni layer and the plated Au layer may be omitted as shown in FIG. 1(b). In some cases, the double-sided wiring board shown in FIG. 1(b) is shipped as it is.

In a double-sided wiring board fabricating method of fabricating the double-sided wiring board shown in FIG. 1(b), there is no plated layer formed on the chip bond pads 170 or the outer pads 170a, which is different from the construction in the double-sided wiring board fabricating method of fabricating the double-sided wiring board shown in FIG. 1(a).

As apparent from the foregoing description, the present invention can provide a double-sided wiring board suitable for high-density packaging, superior to the conventional buildup multilayer wiring board in productivity, and capable of solving problems due to power loss in dealing with high-frequency signals.

Semiconductor chips rarely slide when the semiconductor chips are mounted on the double-sided wiring board of the present invention by wire bonding or flip-chip solder bonding, the conductive plugs filling up the through holes do not have any dents, and the wiring lines have a uniform thickness. Thus, the double-sided wiring board of the present invention is suitable for forming a semiconductor IC package.

The present invention can provide the double-sided wiring board fabricating method of fabricating such a double-sided wiring board.

To meet the reduction of the diameter of lands and the width of wiring layers, a conventional wiring board had a wiring layer formed on each of the surfaces of a core substrate by a subtractive method, and a plated wiring layer formed on each of the wiring layers by an additive method. Such a wiring board has been used for forming CSPs and stack packages.

The two-wiring-layer double-sided wiring board of the present invention provided with the single wiring layer on each of the surfaces of the core substrate is capable of replacing the conventional four-wiring-layer double-sided wiring board.

The two-wiring-layer double-sided wiring board of the present invention, as compared with the conventional four-wiring-layer double-sided wiring board, is simple in construction, capable of being fabricated by reduced processes, and excellent in productivity and solving problems due to power loss in dealing with high-frequency signals.

### Second Embodiment

A second embodiment of the present invention will be described in connection with the accompanying drawings.

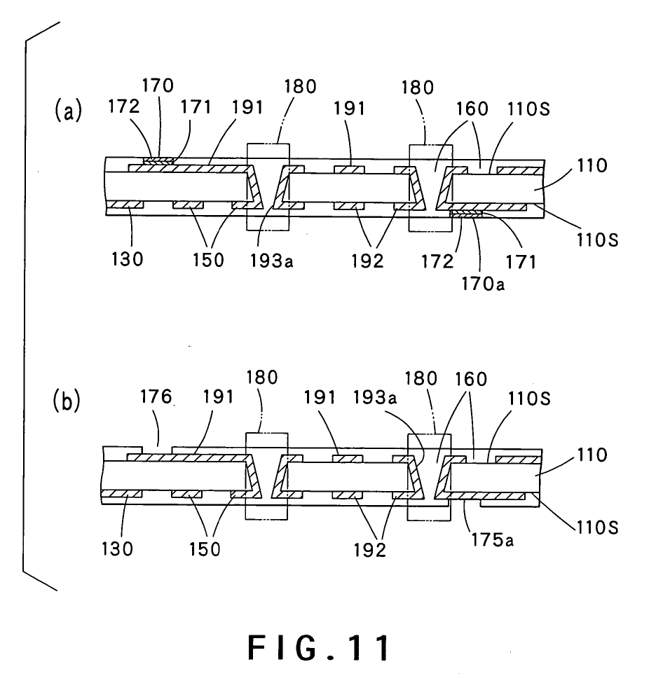

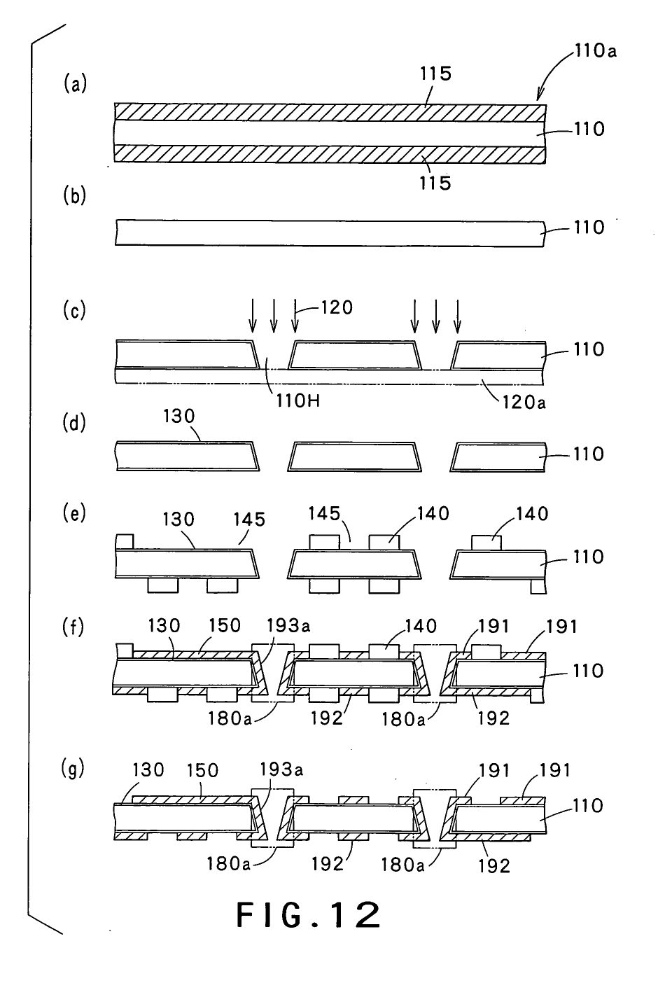

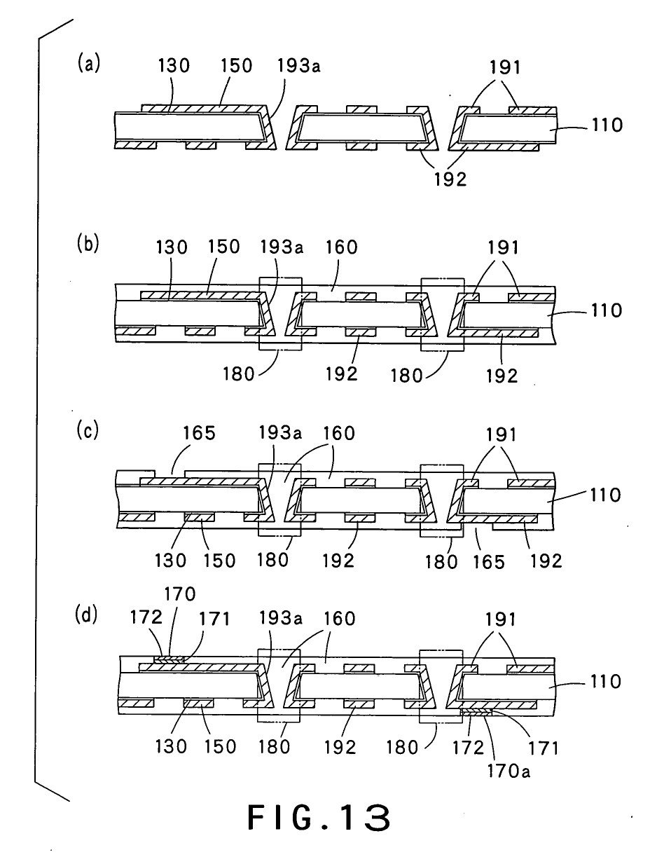

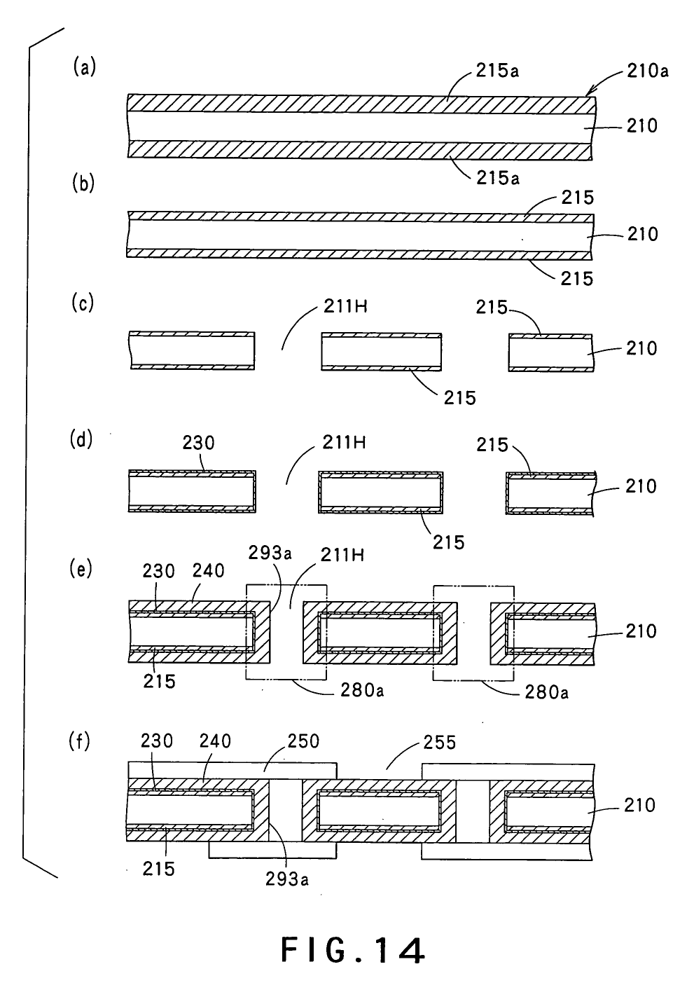

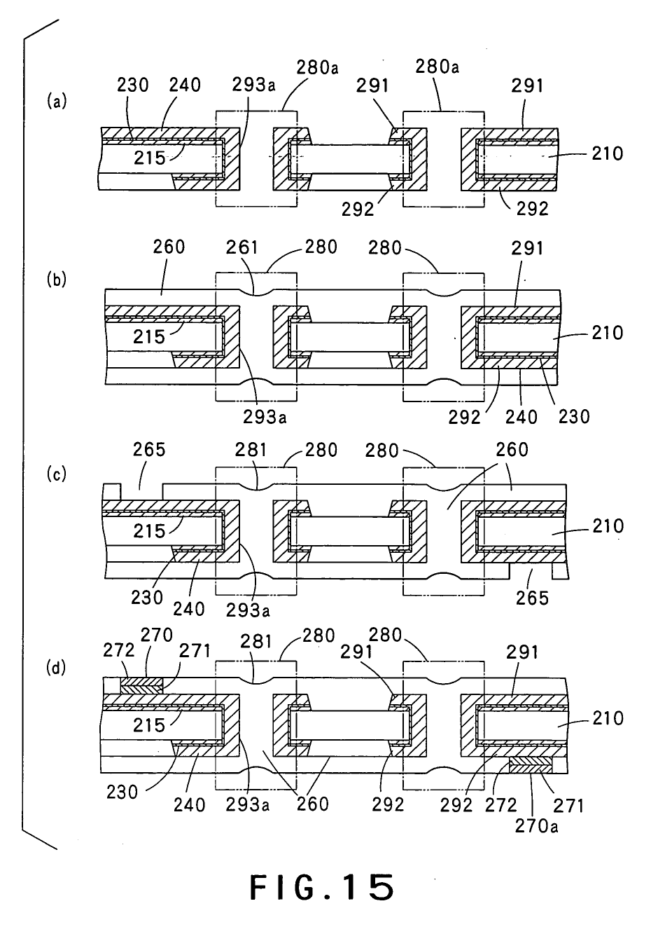

FIG. 11(a) is a fragmentary sectional view of a double-sided wiring board in a second embodiment according to the present invention, FIG. 11(b) is a fragmentary sectional view of a double-sided wiring board in a modification of the second embodiment shown in FIG. 11(a), FIGS. 12(a)-12(g) are sectional views of assistance in explaining steps of a double-sided wiring board fabricating method of fabricating the double-sided wiring board in the second embodiment shown in FIG. 11(a), FIGS. 13(a)-13(d) are sectional views of assistance in explaining steps subsequent to those shown in FIGS. 12(a)-12(g), FIGS. 14(a)-14(f) are sectional views of assistance in explaining steps of a double-sided wiring board fabricating method of fabricating a double-sided wiring board in a comparative example, and FIGS. 15(a)-15(d) are sectional views of assistance in explaining steps subsequent to those shown in FIGS. 14(a)-14(f).

Shown in FIGS. 11(a)-11(b) to 15(a)-15(d) are a core substrate 110, through holes 110H, surfaces 111S of the core substrate 110, electrolytic Cu foils 115, a laser beam 120, electroless-plated layers 130, resist layers 140, open areas 145, electroplated Cu layers 150, solder resist layers 160, open areas 165, chip bond pads (referred to also as inner terminals) 170, outer pads (referred to also as outer terminals) 170a, a plated Ni layer 171, a plated Au layer 172, terminal parts 175 and 175a, connecting parts 180, through hole forming parts 180a, wiring lines 191 and 192, conductive layers 193a formed on the side surfaces of the through holes 110H, a core substrate 210, through holes 211H, electrolytic Cu foils 215a, thin electrolytic Cu foils 215 formed by etching the electrolytic Cu foils 215a, electroless-plated layers 230, electroplated Cu layers 240, resist layers 250, open areas 255, solder resist layers 260, dents 261, open areas 265, terminals 270 and 270a, plated Ni layers 271, plated Au layers 272, connecting parts 280, wiring lines 291 and 292, conductive layers 293 formed on the side surfaces of the through holes 211H.

A double-sided wiring board in a second embodiment according to the present invention will be described with reference to FIG. 11(a).

The double-sided wiring board of the present invention includes a core substrate 110 having opposite roughened surfaces lIOS, and wiring layers 191 and 192 formed on the surfaces 110S of the core substrate 110. The double-sided wiring board is fabricated by a double-sided wiring board fabricating method illustrated in FIGS. 12(a)-12(g) and 13(a)-13(d). Wiring layers or wiring lines 191 and 192 are formed by a semiadditive method respectively on the roughened surfaces 110S of the core substrate 110. The wiring layers 191 and 192 are electrically connected by connecting parts 180. The predetermined inner terminals 170 and predetermined outer terminals 170a are connected to the wiring layers 191 and 192. Solder resist layers 160 are formed on both the surfaces of the core substrate 110 such that the terminals 170 and 170a are exposed. The double-sided wiring board is used for fabricating a semiconductor IC package. The double-sided wiring board can replace the multilayer wiring board 10 used as an interposer in the semiconductor IC package shown in FIG. 9.

Each connecting part 180 is formed by forming the through hole 110H in the core substrate 110 by laser machining, forming the conductive layer 193a on the side surface of the through hole 110H by plating, and filling up the through hole 110H with the solder resist layer 160.

The chip bond pads (inner terminals) 170 are formed on the surface provided with the wiring layers 191 of the core substrate 110. A semiconductor chip is mounted on the double-sided wiring board and the terminals of the semiconductor chip are connected to the chip bond pads 170 by flip-chip solder bonding. The outer terminals 170a are formed on the other surface provided with the wiring lines 192 of the core substrate 110. The outer terminals 170a are connected to external circuits.

Naturally, the chip bond pads 170 and the outer terminals 170a may be selectively formed respectively on the opposite surfaces of the core substrate 110.

Each of the chip bond pads 170 and the outer terminals 170a has the electroplated Cu layer 150 formed on the electroless-plated layer 130, and a laminate structure formed on the electroplated Cu layer 150 and including the plated Ni layer 171 and the plated Au layer 172 formed on the plated Ni layer 171 so as to fill up an opening in the solder resist layer 160.

The surfaces 110S of the core substrate 110 have a ten-point height irregularity Rz (JIS) in the range of 2 to 10 μm. When the surfaces 110S of the core substrate 110 have a ten-point height irregularity Rz in this specified range, adhesive strength between the surfaces 110S and the wiring lines 191 and 192 is high, and the wiring lines 191 and 192 can be formed in very fine ones. Formation of surfaces having such a ten-point height irregularity is practically feasible.

The core substrate 110 is formed by impregnating a fabric, such as glass cloth, nonwoven aramide cloth, nonwoven liquid crystal polymer cloth or Gore Tex®, with an insulating, heat-resistant, thermosetting resin.

Suitable insulating, heat-resistant, thermosetting resins are cyanate resins, BT resins, epoxy resins and PPE resins (polyphenylene ether resins).

Peel strength of a wiring layer formed on a film of a cyanate resin of 679F Series (Hitachi) having surfaces of a ten-point height irregularity Rz of 5 μm as the core substrate 110 measured by a peel strength test method specified in C5012, JIS, Aug. 1, 1987 was 800 g/cm.

The surfaces 110S of the resin core substrate 110 are formed by bonding electrolytic Cu foils 115 (FIGS. 12(a)-12(g)) to the core substrate 110 by thermocompression bonding with the plated surfaces of the electrolytic Cu foils 115 being in contact with the core substrate 110. The shapes of the roughened plated surfaces of the electrolytic Cu foils 115 are transferred to the surfaces 110S of the core substrate (FIGS. 12(a)-12(g) and 13(a)-13(d)) to enhance adhesive strength between the surfaces 110S of the core substrate 110, and the wiring layers 191 and 192.

The connecting parts 180 are formed in parts, provided with the through holes 110H formed by laser machining, of the core substrate 110. Generally, laser machining uses a CO₂ laser or a UV laser. The diameter of the through holes 110H is 150 μm or below.

The electroplated Cu layers 150 forming the wiring lines 191 and 192 and the conductive layers 193a is formed by a known Cu electroplating process. The thickness of the electroplated Cu layers 150 is in the range of about 5 to about 30 μm, in view of conductivity.

The electroless-plated layers 130 are formed by a known electroless Ni or Cu plating process. The electroless-plated layers 130 serve as plating electrodes for forming the wiring layers 191 and 192, and the conductive layers 193a. The electroless-plated layers 130 has a predetermined thickness that permits the electroless-plated layers 130 to be easily removed by flash etching without damaging other parts.

FIG. 11(b) shows a double-sided wiring board similar to the double-sided wiring board shown in FIG. 11(a), except that the former does not have any additional terminals to the terminals 170 and 170a each consisting of the plated Ni layer 171 and the plated Au layer 172 of the latter. In some cases, the double-sided wiring board shown in FIG. 11(b) is shipped as it is.

Parts included in the double-sided wiring board shown in FIG. 11(b) are the same as those of the double-sided wiring board shown in FIG. 11(a), and hence the description thereof will be omitted.

A double-sided wiring board fabricating method of fabricating the double-sided wiring board shown in FIG. 11(a) will be described in connection with FIGS. 12(a)-12(g) and 13(a)-13(d).

This description shall be considered to be the description of a double-sided wiring board fabricating method embodying the present invention.

A three-layer laminated workpiece 110a shown in FIG. 12(a) is formed by bonding electrolytic Cu foils each having a roughened surface to the opposite surfaces of an insulating resin film for forming a core substrate 110 with the roughened surfaces thereof being in contact with the surfaces of the insulating resin film by compression bonding.

The electrolytic Cu foils are bonded to the opposite surfaces of the insulating resin film with layers of a thermosetting resin by thermocompression bonding with the plated, roughened surfaces of the electrolytic Cu foils being in contact with the insulating resin film.

The insulating resin film is produced by impregnating a fabric, such as glass cloth, nonwoven aramide cloth, nonwoven liquid crystal polymer cloth or Gore Tex®, with an insulating resin.

Suitable insulating resins are cyanate resins, BT resins, epoxy resins and PPE resins (polyphenylene ether resins).

Subsequently, the electrolytic Cu foils 115 are removed from the surfaces of the insulating film by etching to obtain the core substrate 110 having surfaces 110S of a shape formed by transferring the shape of the surfaces of the electrolytic Cu foils 115 as shown in FIG. 12(b).

A ferric chloride solution, a cupric chloride solution or an alkaline etching solution is used for etching the electrolytic Cu foils 115.

The core substrate 110 is cleaned, and then through holes 110H are formed in the core substrate 110 by irradiating parts of the core substrate 110 selectively with a laser beam 120 as shown in FIG. 12(c).

The laser beam 120 is emitted by a CO₂ laser or a UV laser depending on the quality of the materials of the core substrate 110.

The through holes 110H are formed in the core substrate 110 by placing a plate 120a that does not excessively reflect a laser beam, such as a black plate, on one of the surfaces of the core substrate 110, and irradiating the core substrate 110 from the side of the other surface of the core substrate 110 with the laser beam 120. The through holes 110H formed in the core substrate 110 by laser machining may be taper through holes having a trapezoidal cross section and tapered from one side of the core substrate from which the laser beam 120 falls on the core substrate 110 toward the other side of the core substrate.

When the core substrate 110 contains a cyanate resin and has a thickness of 100 μm and the through holes 110H are formed by laser machining using CO₂ laser, each of the through holes 110H has a large end of a diameter of 100 μm and a small end of a diameter of 70 μm.

The taper through holes 110H facilitate filling up the through holes 110H with solder resist layers 160. The solder resist layers 160 are formed on the opposite surfaces of the core substrate 110 after planarizing through hole regions corresponding to the through holes 110H.

Through holes of the conventional core substrate are formed by mechanical drilling. It is difficult to form the through holes in a diameter below 150 μm. According to the present invention, the through holes 110H of a diameter not greater than 150 μm can be formed in the core substrate 110 by laser machining.

The minimum possible diameter of the through holes 110H is 80 μm when a CO₂ laser is used for laser machining or about 25 μm when a UV-YAG laser is used for laser machining.

The core substrate 110 is subjected to a desmearing process to remove residual chips produced by laser machining before forming the electroless-plated Cu layers. Then, the core substrate 110 is subjected to electroless plating to plate the core substrate entirely with conductive electroless-plated layers 130 as shown in FIG. 12(d).

The electroless-plating of the core substrate 110 can be achieved by a known Cu or Ni electroless plating process.

Then, resist layers 140 are formed on both the surfaces of the core substrate 110. The resist layers 140 are provided with openings 145 corresponding to regions in which wiring layers 191 and 192, and conductive layers 193a included in connecting parts 180 are to be formed as shown in FIG. 12(e). Then, electroplated Cu layers 150 are formed by Cu electroplating using the electroless-plated layers 130 as plating electrodes to form the wiring layers 191 and 192 on the core substrate 110, and the conductive layers 193a on the through holes 110H as shown in FIG. 12(f).

Since the electroless-plated layers 130 formed by a known plating process, such as a Cu or Ni electroless plating process, serve only as plating electrodes for forming the electroplated Cu layers 150 for forming the wiring layers 191 and 192, the electroless-plated layers 130 need a predetermined thickness that permits the electroless-plated layers 130 to be easily removed by flash etching without damaging other parts.

The resist layers 140 may be formed of any type of resist, provided that the resist layers 140 can be patterned in a desired resolution, and is resistant to plating actions and satisfactory in workability.

Usually, dry resist films are used as the resist layers 140 because dry resist films are easy to handle.

Then, the resist layers 140 are removed (FIG. 12(g)), and exposed, unnecessary parts of the electroless-plated layers 130 are removed by flash etching as shown in FIG. 13(a).

Suitable etching solutions for flash etching include mixture of sulfuric acid with hydrogen peroxide solutions, persulfuric acid solutions, hydrochloric acid solutions, nitric acid solutions, cyanide solutions and organic etching solutions.

A photosensitive solder resist is applied to both the surfaces of the core substrate 110 to form solder resist layers 160 on both the surfaces of the core substrate 110, and to fill up the through holes 110H as shown in FIG. 13(b).

When the solder resist is applied to the surface, provided with the wiring layers 191 and having the large ends of the through holes 110H, of the core substrate 110, the solder resist does not easily go out through the small ends of the through holes 110H on the other surface provided with the wiring lines 192. Thus, the solder resist can be easily filled in the through holes 110H, and the solder resist layers 160 having flat surfaces can be securely formed on both the surfaces of the core substrate 110 including the connecting parts 180.

Subsequently, the solder resist layers 160 are exposed through a predetermined photomask, the exposed solder resist layers 160 are developed to expose areas corresponding to chip bond pads 170 and outer pads 170a as shown in FIG. 13(c).

Subsequently, the chip bond pads 170 and the outer pads 170a are formed as shown in FIG. 13(d) by depositing a plated Ni layer 171 and a plated Au layer 172 in that order on the surfaces of the exposed areas corresponding to the chip bond pads 170 and the outer pads 170a.

Thus, the double-sided wiring board in the second embodiment is completed.

A double-sided wiring board in a comparative example comparing with the double-sided wiring board shown in FIG. 11(a) will be described. The double-sided wiring board in a comparative example has a core substrate provided, similarly to the conventional core substrate shown in FIG. 17, with wiring layers formed on both the surfaces, and through holes formed by mechanical drilling and having plated side surfaces connecting wiring lines formed by processing the wiring layers. The through holes of the core substrate are filled up with a solder resist, and the wiring lines formed on both the surfaces of the core substrate are coated with solder resist layers. The double-sided wiring board in a comparative example for a semiconductor IC package will be described with reference to FIGS. 14(a)-14(f) and 15(a)-15(d).

A three-layer laminated workpiece 210a is fabricated by bonding electrolytic Cu foils 215a to both the surfaces of a core substrate 210 by thermocompression bonding as shown in FIG. 14(a). Then, the electrolytic Cu foils 215a bonded to both the surfaces of the core substrate 210 are thinned in a desired thickness by etching as shown in FIG. 14(b). Subsequently, through holes 211H are formed in the workpiece 210a as shown in FIG. 14(c) by mechanical drilling. The workpiece is subjected to a polishing process to remove flashes, and to a desmearing process for cleaning. Then, electroless-plated layers 230 are formed on the workpiece 210a by electroless plating as shown in FIG. 14(d). Then, electroplated Cu layers 240 are formed on both the surfaces of the core substrate 210, and conductive layers 293a are formed on the side surfaces of the through holes 211H as shown in FIG. 14(e) by Cu electroplating using the electroless-plated layers 230 as plating electrodes.

Subsequently, resist layers 250 resistant to etching and provided with openings 255 in predetermined parts thereof are formed on both the surfaces of the core substrate 210 as shown in FIG. 14(f). Parts of the electroplated layers 240, the electroless-plated layers 230 and the thin electrolytic Cu foils 215 corresponding to the openings 255 of the resist layers 250 are removed by etching using an etchant, such as a ferric chloride solution, as shown in FIG. 15(a). Then, the resist layers 250 are removed, and solder resist layers 260 of a photosensitive solder resist are formed on both the surfaces of the core substrate 210 so as to fill up the through holes 210H as shown in FIG. 15(b).

Then, openings are formed in parts, corresponding to terminal forming areas 265, of the solder resist layers 260 by photolithography as shown in FIG. 15(c). A plated Ni layer 271 and a plated Au layer 272 are formed in that order on exposed parts of the electroplated Cu layers 240. Thus, the double-sided wiring board in a comparative example as shown in FIG. 15(d) is completed.

This double-sided wiring board fabricating method forms the wiring lines by etching the electrolytic Cu foils 215, the electroless-plated layers 230 and the electroplated Cu layers 240, which are previously prepared. Thus, this double-sided wiring board fabricating method forms the wiring lines by processes basically similar to those of the method illustrated in FIG. 7 that uses principally a subtractive method that etches wiring layers, and is unable to cope with the miniaturization of wiring lines and the increase of packaging density.

Therefore, it is difficult to fabricate a double-sided wiring board provided with wiring lines of a width on the order of 50 μm or less arranged at line spacing on the order of 50 μm or less by this method. The through holes 211H formed by mechanical drilling have a large diameter. Therefore, the core substrate similarly to the conventional core substrate shown in FIG. 7(d), cannot be provided with through holes of a diameter below 150 μm and lands of a diameter below 350 μm.

Since the through holes 211H formed by mechanical drilling have a large diameter, dents 261 are formed in the end surfaces of plugs of the solder resist 260 filling up the through holes 211H. Consequently, bubbles are included in spaces defined by the dents 261 and a semiconductor chip mounted on the double-sided wiring board, thereby the reliability of a semiconductor device is reduced, and load on customer's work for mounting a semiconductor chip on the double-sided wiring board is increased.

The double-sided wiring board in a comparative example has the foregoing problems and is unsuitable for high-density packaging.

As apparent from the foregoing description, the present invention can provide a double-sided wiring board suitable for high-density packaging, superior to the conventional buildup multilayer wiring board in productivity.

To meet the reduction of the diameter of lands and the width of wiring lines, a conventional wiring board had a wiring layer formed on each of the surfaces of a core substrate by a subtractive method, and a plated wiring layer formed on each of the wiring layers by an additive method. Such a wiring board has been used for forming CSPs and stack packages. The two-wiring-layer double-sided wiring board of the present invention provided with the single wiring layer on each of the surfaces of the core substrate is capable of replacing the conventional four-wiring-layer double-sided wiring board.

The two-wiring-layer double-sided wiring board of the present invention, as compared with the conventional four-wiring-layer double-sided wiring board, is simple in construction, capable of being fabricated by reduced processes, and excellent in productivity.

Since any dents are not formed in the solder resist layers of the double-sided wiring board of the present invention, load on customer's processes can be reduced.

Modification

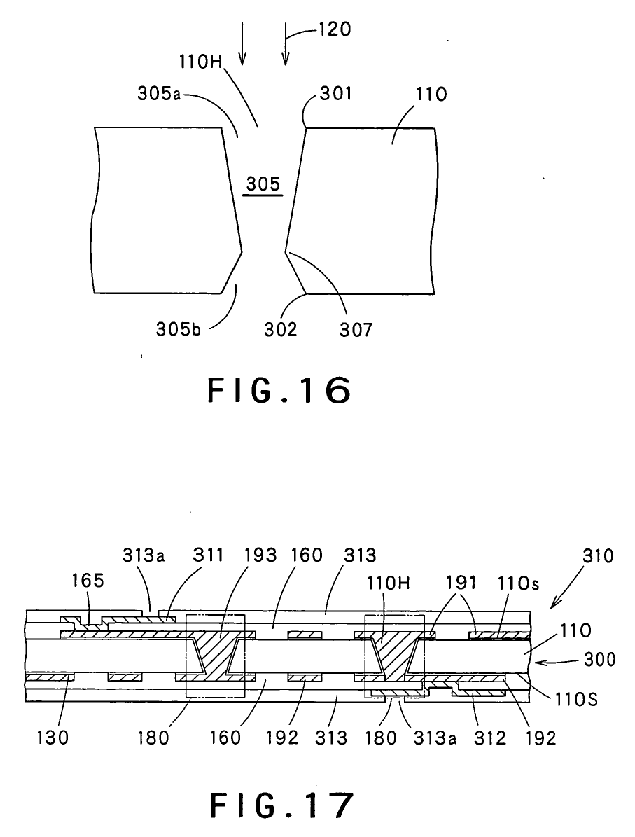

A modification of the present invention will be described in connection with FIGS. 16 to 18.

The double-sided wiring board according to the modification shown in FIG. 16 has a core substrate 110 and a through hole 110H formed in the core substrate 110 which has a different cross section from that in the double-sided wiring boards of the first and second embodiments. Other parts of the double-sided wiring board of the modification are substantially the same as those of the double-sided wiring boards of the first and second embodiments.

The core substrate 110 is formed by impregnating a fabric, such as glass cloth, nonwoven aramide cloth, nonwoven liquid crystal polymer cloth or porous polytetrafluoroethylene cloth, with an insulating resin. The through hole 110H is formed by irradiating the laser beam 120 on the core substrate 110. An energy of the laser beam 120 is adjusted such that the through hole 110H has a cross section shown in FIG. 16.

The cross section of the though hole 110H consists of a first trapezoidal cross section 305a which is tapered from one end 301 of the through hole 110H to the inside, and a second trapezoidal cross section 305b which is tapered from the other end 302 of the through hole 110H to the inside. The first trapezoidal cross section 305a on a side of one end 301 and the second trapezoidal cross section 305b on a side of the other end 302 are separated from each other at an internal point 307 of the through hole 110H as a boundary.

As described above, a cross section 305 of the through hole 110H is composed of the first trapezoidal cross section 305a on the side of the one end 301 and the second trapezoidal cross section 305b on the side of the other end 302. Thus, when the conductive plug 193 is formed by filling up the through hole 110H with an electroplated layer from the one end 301 (see FIG. 2(f)), since the electroplated material is supplied to the first trapezoidal cross section 305a with being pressed toward the internal point 307, the first trapezoidal cross section 305a is surely filled up with the electroplated layer. Then, the electroplated material is smoothly supplied to the second trapezoidal cross section 305b in an expanded manner, so that the second trapezoidal cross section 305b is surely filled up with the electroplated layer.

A buildup multilayer wiring board 310 will be described in connection with FIG. 17.

As shown in FIG. 17, the multilayer wiring board 310 includes a double-sided wiring board 300 which is the same as that of the first embodiment, and additional wiring layers 311 and 312 formed on both sides of the double-sided wiring board 310 through insulating resin layers 160.

The double-sided wiring board 300 has a core substrate 110 having two roughened surfaces 110S, and wiring layers 191 and 192 formed on both the surfaces 110S of the core substrate 110. A though hole 110H forming a connecting part 180 is formed in the core substrate 110. The wiring layers 191 and 192 are electrically connected to each other through the through hole 110H filled up with a conductive plug 193. Electroless-plated layers 130 are formed on the surfaces 110S of the core substrate 110 and the through hole 110H.

The wiring layers 191 and 192 are coated with the insulating resin layers 160 having open areas 165. The additional wiring layers 311 and 312 are connected to the wiring layers 191 and 192 through the open areas 165 of the insulating resin layers 160. Open areas 313a formed in the additional wiring layers 311 and 312 serve as additional terminals 313a.

The multilayer wiring board 310 shown in FIG. 17 includes four wiring layers 311, 191, 192, and 312 which are described above.

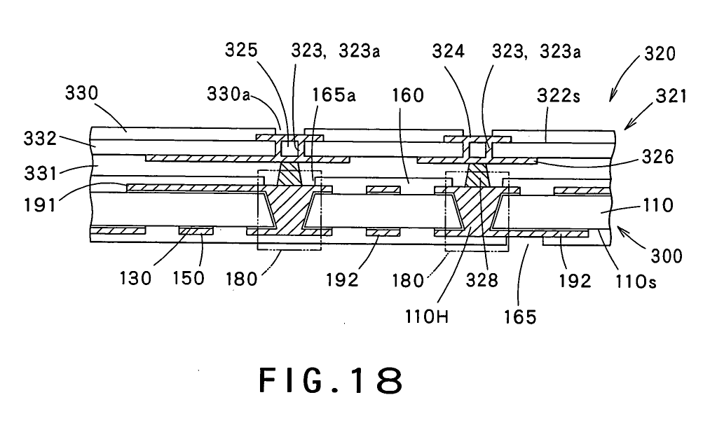

A multilayer wiring board 320 having a bump will be described in connection with FIG. 18. As shown in FIG. 18, the multilayer wiring board 320 has a double-sided wiring board 300 and an additional wiring board 321 formed on an upper side of the double-sided wiring board 300 through an insulating resin layer 160.

The double-sided wiring board 300 has a core substrate 110 having two roughened surfaces 110S, and wiring layers 191 and 192 formed on both the surfaces 110S of the core substrate 110. A though hole 110H forming a connecting part 180 is formed in the core substrate 110. The wiring layers 191 and 192 are electrically connected to each other through the through hole 110H filled up with a conductive plug 193. Electroless-plated layers 130 are formed on the surfaces 110S of the core substrate 110 and the through hole 110H.

The wiring layers 191 and 192 are coated with the insulating resin layers 160 having open areas 165. A bump 328 in communication with the conductive plug 193 is formed in open areas 165 of the insulating resin layers 160.

The additional wiring layer 321 has an additional core substrate 322 having two roughened surfaces 322S, and wiring layers 324 and 326 formed on both the surfaces 322S of the additional core substrate 322. The additional core substrate 322 has an additional through hole 323 in which a conductive layer 323a is formed. The additional through hole 323 is filled up with a resist layer 325.

The wiring layer 324 of the additional wiring board 321 is covered with an additional resin layer 330 having an open area 330a.

The bump 328 is disposed on the conductive plug 193 filling up the through hole 110H of the double-sided wiring board 300 to be communicated with the conductive plug 193. The additional through hole 323 of the additional wiring board 321 is positioned to correspond to the bump 328.

The wiring layer 191 and the conductive plug 193 of the double-sided wiring board 300 are connected to the wiring layer 326 of the additional wiring board 321 through the bump 328. An additional insulating resin layer 331 covering the wiring line 326 and the bump 328 is formed between the double-sided wiring board 300 and the additional wiring board 321.

The multilayer wiring board 320 shown in FIG. 18 includes four wiring layers 324, 326, 191, and 192 which are described above.

1. A double-sided wiring board comprising:
a core substrate having two roughened surfaces; and
wiring layers formed on both the surfaces of the core substrate;
wherein the wiring layers are electrically connected through a through hole formed in the core substrate.

2. The double-sided wiring board according to claim 1, wherein
a conductive plug is formed in the through hole by filling up the through hole with a conductive material.

3. The double-sided wiring board according to claim 2, wherein
solder resist layers are formed on the wiring layers formed on both the surfaces of the core substrate so as to expose terminals.

4. The double-sided wiring board according to claim 2, wherein
the outer surfaces of the wiring layers formed on both the surfaces of the core substrate are flush with the end surfaces of the conductive plugs.

5. The double-sided wiring board according to claim 2, wherein
both the surfaces of the core substrate have a ten-point height irregularity Rz specified in JIS in the range of 2 to 10 μm.

6. The double-sided wiring board according to claim 2, wherein
the double-sided wiring board is a board for a semiconductor IC package.

7. The double-sided wiring board according to claim 3, wherein
the terminals formed on one of the surfaces of the core substrate are connection pads to be connected to a semiconductor chip, and the terminals formed on the other surface are those to be connected to external circuits.

8. The double-sided wiring board according to claim 3, wherein
each of terminals formed on both the surfaces of the core substrate has a plated Ni layer and a plated Au layer formed in that order.

9. The double-sided wiring board according to claim 1, wherein
the side surface of the through hole is coated with a plated conductive layer, and the through hole is filled up with a resist.

10. The double-sided wiring board according to claim 9, wherein
solder resist layers are formed on the wiring layers formed on both the surfaces of the core substrate so that terminals are exposed.

11. The double-sided wiring board according to claim 9, wherein
both the surfaces of the core substrate has a ten-point height irregularity Rz specified in JIS in the range of 2 to 10 μm.

12. The double-sided wiring board according to claim 9, wherein
the double-sided wiring board is a board for a semiconductor IC package.

13. The double-sided wiring board according to claim 10, wherein
the terminals formed on one of the surfaces of the core substrate are connection pads to be connected to a semiconductor chip, and the terminals formed on the other surface are those to be connected to external circuits.

14. The double-sided wiring board according to claim 10, wherein
each of terminals formed on both the surfaces of the core substrate has a plated Ni layer and a plated Au layer formed in that order.

15. The double-sided wiring board according to claim 1, wherein
the through hole of the core substrate has a trapezoidal cross section.

16. The double-sided wiring board according to claim 1, wherein
the through hole of the core substrate has a first trapezoidal cross section which is tapered from one end of the through hole toward inside, and a second trapezoidal cross section which is tapered from the other end of the through hole to the inside.

17. The double-sided wiring board according to claim 16, wherein
the first trapezoidal cross section of the through hole is larger than the second trapezoidal cross section thereof.

18. A double-sided wiring board fabricating method of fabricating a double-sided wiring board including a core substrate having two roughened surfaces, and wiring layers formed on both the surfaces of the core substrate and electrically connected through a through hole formed in the core substrate, said double-sided wiring board fabricating method comprising the steps of:
laminating Cu foils each having a roughened surface to the surfaces of an insulating resin film for forming the core substrate with the roughened surfaces thereof in contact with the insulating resin film, respectively, by a contact-bonding process;
removing the Cu foils attached to the insulating resin film by an etching process and transferring the shapes of the roughened surfaces of the Cu foils to the surfaces of the insulating resin film to form the core substrate;
forming a through hole in the core substrate by a laser machining process;
forming electroless-plated layers on the surfaces of the core substrate and the side surface of the through hole by an electroless plating process;
forming electroplated Cu layers by a Cu-electroplating process using the electroless-plated layers as conductive layers after forming patterned resist layers on the surfaces of the core substrate; and
removing exposed unnecessary parts of the electroless-plated layers by a flash etching process after removing the patterned resist layers.

19. The double-sided wiring board fabricating method according to claim 18, wherein
conductive plug is formed so as to fill up the through hole when the electroplated Cu layers are formed.

20. The double-sided wiring board fabricating method according to claim 19, wherein
the side surface of the through hole is subjected to a desmearing process before forming the electroless-plated layers.

21. The double-sided wiring board fabricating method according to claim 19, wherein
the electroplated Cu layers are planarized by mechanical or chemical-mechanical polishing.

22. The double-sided wiring board fabricating method according to the claim 19 further comprising the steps of:
after removing the electroless-plated layers by flash etching, forming solder resist layers of a photosensitive solder resist on the electroplated Cu layers formed on the surfaces of the core substrate; and
exposing the solder resist layers through masks, and developing the exposed solder resist layers to expose parts of the electroplated Cu layers to form terminals.

23. The double-sided wiring board fabricating method according to claim 19, wherein
the roughened surfaces of the Cu foils to be attached by the contact-bonding process to the insulating resin film have a ten-point height irregularity Rz specified in JIS in the range of 2 to 10 μm.

24. The double-sided wiring board fabricating method according to claim 19, wherein
the through hole is formed in the core substrate by placing a plate that does not excessively reflect a laser beam on one of the surfaces of the core substrate, and irradiating the core substrate from the side of the other surface of the core substrate with a laser beam.

25. The double-sided wiring board fabricating method according to claim 22, wherein
a plated Ni layer and a plated Au layer are formed in that order on the surface of each of the terminals.

26. The double-sided wiring board fabricating method according to claim 19, wherein
dry resist films are applied to the surfaces of the core substrate, the dry resist films are exposed through masks, and the exposed dry resist films are developed to form the patterned resist films when the electroplated Cu layers are formed.

27. The double-sided wiring board fabricating method according to claim 18 further comprising the steps of:
after removing the electroless-plated layers by a flash etching process, forming solder resist layers on the surfaces of the electroplated Cu layers formed on the core substrate by applying a photosensitive solder resist to the electroplated Cu layers and filling up the through hole with the solder resist; and
exposing parts of the electroplated Cu layers to form terminals by exposing the solder resist layers through masks, and developing the exposed solder resist layers.

28. The double-sided wiring board fabricating method according to claim 27, wherein
the roughened surfaces of the Cu foils to be attached by the contact-bonding process to the insulating resin film have a ten-point height irregularity Rz specified in JIS in the range of 2 to 10 μm.

29. The double-sided wiring board fabricating method according to claim 27, wherein
the through hole is formed in the core substrate by placing a plate that does not excessively reflect a laser beam on one of the surfaces of the core substrate, and irradiating the core substrate from the side of the other surface of the core substrate with a laser beam.

30. The double-sided wiring board fabricating method according to claim 27, wherein
a plated Ni layer and a plated Au layer are formed in that order on the surface of each of the terminals.

31. The double-sided wiring board fabricating method according to claim 27, wherein
dry resist films are applied to the surfaces of the core substrate, the dry resist films are exposed through masks, and the exposed dry resist films are developed to form the patterned resist films when the electroplated Cu layers are formed.

32. A multilayer wiring board comprising: a double-sided wiring board which includes a core substrate having two roughened surfaces and wiring layers formed on both the surfaces of the core substrate, respectively, the wiring layers being electrically connected through a through hole formed in the core substrate; and
an additional wiring board formed on one side of the double-sided wiring board through an insulating resin layer, wherein
the additional wiring layer including an additional core substrate having two roughened surfaces and additional wiring layers formed on both the surfaces of the additional core substrate, and
the additional wiring layers are electrically connected through an additional through hole formed in the additional core substrate.

33. The multilayer wiring board according to claim 32, wherein
the double-sided wiring board and the additional wiring board are connected to each other through a bump.

34. The multilayer wiring board according to claim 33, wherein
the bump is positioned at a portion corresponding to the through hole of the double-sided wiring board.

35. The multilayer wiring board according to claim 34, wherein
a conductive plug is formed in the through hole of the double-sided wiring board by filling up the through hole with a conductive material.

36. A multilayer wiring board comprising:
a double-sided wiring board having two roughened surfaces and wiring layers formed on both the surfaces of the core substrate, respectively, the wiring layers being electrically connected through a through hole formed in the core substrate; and
additional wiring layers formed on both sides of the double-sided wiring layer through insulating resin layers.

37. The multilayer wiring board according to claim 36, wherein
the additional insulating resin layers are formed on the respective additional wiring layers so as to expose additional terminals.
